(19) United States
(12) Patent Application Publication
(10) Pub. No.: US 2025/0143143 A1
(43) Pub. Date: May 1, 2025

(54) DISPLAY DEVICE

(71) Applicant: Samsung Display Co., Ltd., Yongin-si (KR)

(72) Inventors: Kiho Bang, Yongin-si (KR); Hangjae Lee, Yongin-si (KR); Wonsuk Choi, Yongin-si (KR)

(73) Assignee: Samsung Display Co., Ltd., Yongin-si (KR)

(21) Appl. No.: 18/752,151

(22) Filed: Jun. 24, 2024

(30) Foreign Application Priority Data
Oct. 26, 2023 (KR) 10-2023-0145080

(51) Int. Cl. H10K 59/80; H10K 59/122; H10K 59/131; H10K 59/40

(52) U.S. Cl. CPC H10K 59/873; H10K 59/122; H10K 59/131; H10K 59/40

(57) ABSTRACT

A display device includes a substrate including a display area and a peripheral area adjacent to the display area, a plurality of light-emitting diodes arranged in the display area, a first inorganic encapsulation layer disposed on the plurality of light-emitting diodes, an organic encapsulation layer disposed on the first inorganic encapsulation layer, a plurality of inorganic patterns disposed on the organic encapsulation layer and spaced apart from each other, and a touch electrode disposed on the organic encapsulation layer and defining a plurality of electrode holes respectively overlapping the plurality of light-emitting diodes in a plan view.

### CROSS-REFERENCE TO RELATED APPLICATION(S)

This application claims priority to and benefits of Korean Patent Application No. 10-2023-0145080 under 35 U.S.C. § 119, filed on Oct. 26, 2023, in the Korean Intellectual Property Office (KIPO), the entire contents of which are incorporated herein by reference.

### BACKGROUND

### 1. Technical Field

The disclosure relates to a display device.

### 2. Description of the Related Art

Mobile electronic devices include display devices for providing users with visual information such as images or videos. With the development of display devices, various display devices having excellent characteristics, such as thinness, light weight, and low power consumption, have been introduced. With the miniaturization of components for driving the display devices, the proportions of the display devices in the electronic devices have gradually increased, and the display devices having structures that are bendable or foldable to have certain angles have also been developed.

### SUMMARY

A display device may include a display panel configured to display an image. The display panel may include an area bendable in a rear direction of the display panel, and stress may be concentrated on the bent area.

Embodiments include a display device in which reliability is improved by preventing or reducing damage caused by concentration of stress.

Additional aspects will be set forth in part in the description which follows and, in part, will be apparent from the description, or may be learned by practice of the embodiments of the disclosure.

According to an embodiment, a display device may include a substrate including a display area and a peripheral area adjacent to the display area, a plurality of light-emitting diodes arranged in the display area, a first inorganic encapsulation layer disposed on the plurality of light-emitting diodes, an organic encapsulation layer disposed on the first inorganic encapsulation layer, a plurality of inorganic patterns disposed on the organic encapsulation layer and spaced apart from each other, and a touch electrode disposed on the organic encapsulation layer and defining a plurality of electrode holes respectively overlapping the plurality of light-emitting diodes in a plan view.

Each of the plurality of inorganic patterns may cover one of the plurality of light-emitting diodes in a plan view, and the plurality of inorganic patterns may be respectively arranged inside the plurality of electrode holes in a plan view.

Each of the plurality of inorganic patterns may cover two or more of the plurality of light-emitting diodes in a plan view, and each of the plurality of inorganic patterns may overlap two or more of the plurality of electrode holes in a plan view.

A first opening may be defined between the plurality of inorganic patterns, and the first opening may overlap at least a portion of the touch electrode in a plan view.

A portion of the touch electrode, which overlaps the first opening in a plan view, may be in direct contact with the organic encapsulation layer, and a remaining portion of the touch electrode may be disposed on the plurality of inorganic patterns.

The plurality of inorganic patterns may include a first inorganic layer and a second inorganic layer.

The display device may further include a first inorganic layer disposed on the plurality of inorganic patterns and covering the first opening, wherein the touch electrode may be disposed on the first inorganic layer.

The display device may further include an organic layer disposed on the plurality of inorganic patterns and filling the first opening, wherein the touch electrode may be disposed on the organic layer.

Each of the plurality of light-emitting diodes may include a pixel electrode, an opposing electrode, and an emission layer arranged between the pixel electrode and the opposing electrode. The display device may further include a pixel-defining layer defining a plurality of pixel openings exposing center portions of pixel electrodes, and a metal bank layer disposed on the pixel-defining layer, including a first sub-metal layer and a second sub-metal layer on the first sub-metal layer, and defining a plurality of openings overlapping the plurality of pixel openings in a plan view. The second sub-metal layer may include tips protruding from a side surface of the first sub-metal layer to a center direction of each of the plurality of pixel openings.

The opposing electrode may be in direct contact with the side surface of the first sub-metal layer.

The first inorganic encapsulation layer may be in direct contact with a bottom surface of the tips and the side surface of the first sub-metal layer.

A width of each of the plurality of inorganic patterns may be greater than a width of ones of the plurality of pixel openings overlapping the plurality of inorganic patterns in a plan view.

The display device may further include a common voltage line arranged in the peripheral area, and a second inorganic encapsulation layer disposed on the organic encapsulation layer and overlapping the common voltage line in a plan view. The second inorganic encapsulation layer may define a second opening extending in a direction parallel to an edge of the substrate.

The second opening may overlap the organic encapsulation layer in a plan view.

The second opening may surround at least a portion of the display area in a plan view.

According to an embodiment, a display device may include a substrate including a display area and a peripheral area adjacent to the display area, a plurality of light-emitting diodes arranged in the display area, a first inorganic encapsulation layer disposed on the plurality of light-emitting diodes and extending to the peripheral area, an organic encapsulation layer disposed on the first inorganic encapsulation layer, and a second inorganic encapsulation layer disposed on the organic encapsulation layer and defining a first opening in the peripheral area.

The first opening may overlap the organic encapsulation layer in a plan view.

The display device may further include a common voltage line arranged in the peripheral area and surrounding at least a portion of the display area in a plan view, an organic insulating layer arranged between the substrate and the plurality of light-emitting diodes, and overlapping a boundary of the common voltage line at one side by extending from the display area to the peripheral area in a plan view, and a dam overlapping a boundary of the common voltage line at another side in a plan view.

The first opening may be disposed closer to the display area than to an end of the organic insulating layer.

The peripheral area may be bent with a curvature in a rear direction of the substrate.

Other aspects, features, and advantages may become clear from the following drawings, the claims, and the detailed description of the disclosure.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a perspective view of a display device according to an embodiment;

FIG. 2A is a schematic cross-sectional view of the display device taken along line A-A′ of FIG. 1;

FIG. 2B is a schematic cross-sectional view of the display device taken along line B-B′ of FIG. 1;

FIG. 2C is a schematic cross-sectional view of the display device taken along line C-C′ of FIG. 1;

FIG. 3 is a plan view of a display panel included in a display device, according to an embodiment;

FIG. 4A is a schematic diagram of an equivalent circuit of a pixel included in a display device, according to an embodiment;

FIG. 4B is a schematic diagram of an equivalent circuit of a pixel included in a display device, according to an embodiment;

FIG. 5A is a plan view of a portion of region G of the display panel of FIG. 3 according to an embodiment;

FIG. 5B is a plan view of a portion of region G of the display panel of FIG. 3 according to an embodiment;

FIG. 5C is an enlarged plan view of region H illustrated in FIG. 5B;

FIG. 6A is a plan view of a portion of a display panel, according to an embodiment;

FIG. 6B is a schematic cross-sectional view of the display panel taken along line I-I′ of FIG. 6A;

FIG. 6C is a schematic cross-sectional view of the display panel taken along line I-I′ of FIG. 6A;

FIG. 7A is a plan view of a portion of a display panel, according to an embodiment;

FIG. 7B is a schematic cross-sectional view of the display panel taken along line J-J′ of FIG. 7A;

FIG. 7C is a schematic cross-sectional view of the display panel taken along line J-J′ of FIG. 7A;

FIG. 8A is a schematic cross-sectional view of a portion of a display panel, according to an embodiment;

FIG. 8B is a schematic cross-sectional view of a portion of a display panel, according to an embodiment;

FIG. 9A is a schematic cross-sectional view of a portion of a display panel, according to an embodiment;

FIG. 9B is a schematic cross-sectional view of a portion of a display panel, according to an embodiment;

FIG. 10 is a schematic cross-sectional view of a portion of a display panel, according to an embodiment;

FIG. 11 is a schematic cross-sectional view of a portion of a display panel, according to an embodiment;

FIG. 12 is a schematic cross-sectional view of the display panel taken along line E-E′ of FIG. 3; and

FIG. 13 is a plan view of a display panel included in a display device, according to an embodiment.

### DETAILED DESCRIPTION OF THE EMBODIMENTS

The disclosure may have various modifications and various embodiments, and specific embodiments are illustrated in the drawings and are described in detail in the detailed description. Effects and features of the disclosure and methods of achieving the same will become apparent with reference to embodiments described in detail with reference to the drawings. However, the disclosure is not limited to the embodiments described below, and may be implemented in various forms.

Hereinafter, embodiments will be described in detail with reference to the accompanying drawings, and in the following description with reference to the drawings, like reference numerals refer to like elements and redundant descriptions thereof will be omitted.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

In the specification, an expression used in the singular encompasses the expression of the plural, unless it has a clearly different meaning in the context.

In the specification, it will be further understood that the terms “comprise” and/or “comprising” used herein specify the presence of stated features or components, but do not preclude the presence or addition of one or more other features or components.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification, an x direction, a y direction, and a z direction are not limited to directions in three axes on an orthogonal coordinate system, but may be interpreted in a broad sense including the three axes. For example, the x direction, the y direction, and the z direction may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

In the drawings, for convenience of description, sizes of components may be exaggerated or reduced. In other words, because sizes and thicknesses of components in the drawings are arbitrarily illustrated for convenience of explanation, the disclosure is not necessarily limited thereto.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

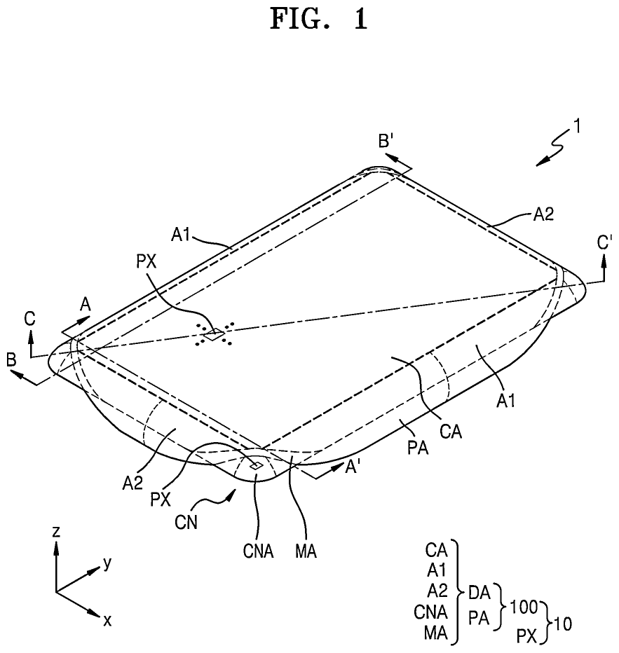

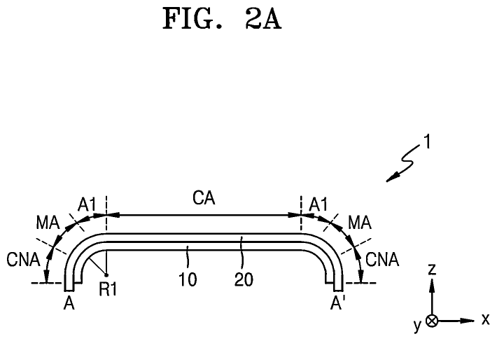

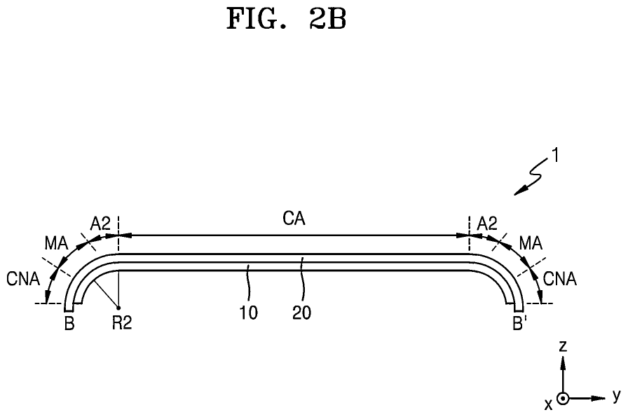

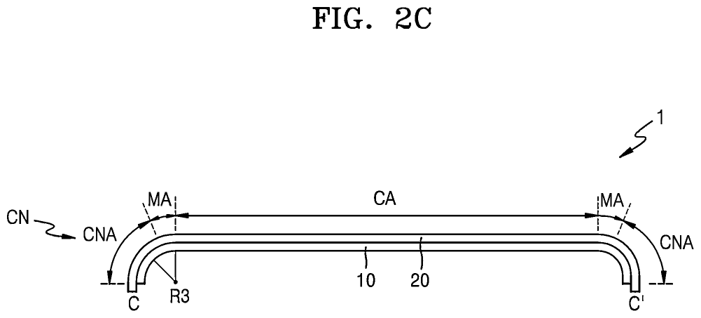

FIG. 1 is a perspective view schematically showing a display device 1 according to an embodiment. FIG. 2A is a schematic cross-sectional view of the display device 1 taken along line A-A′ of FIG. 1. FIG. 2B is a schematic cross-sectional view of the display device 1 taken along line B-B′ of FIG. 1. FIG. 2C is a schematic cross-sectional view of the display device 1 taken along line C-C′ of FIG. 1.

Referring to FIGS. 1 and 2A to 2C, the display device 1 may display an image. The display device 1 may include an edge extending in a first direction and an edge extending in a second direction. The first direction and the second direction may intersect each other. For example, the first direction and the second direction may form an acute angle. For example, the first direction and the second direction may form an obtuse angle or a right angle. Hereinafter, an embodiment in which the first direction and the second direction form a right angle will be described. For example, the first direction may be an x direction or a −x direction, and the second direction may be a y direction or a −y direction.

According to an embodiment, a corner CN where the edge in the first direction (e.g., the x direction or −x direction) and the edge in the second direction (e.g., the y direction or the −y direction) meet may have a specific curvature.

The display device 1 may include a cover window 20 and a display panel 10. The cover window 20 may protect the display panel 10. According to an embodiment, the cover window 20 may be disposed on the display panel 10. According to an embodiment, the cover window 20 may be a flexible window. The cover window 20 may protect the display panel 10 by bending readily in response to an external force without causing a crack or the like. The cover window 20 may include glass, sapphire, or plastic. The cover window 20 may include, for example, ultra-thin glass or colorless polyimide.

The display panel 10 may be disposed below the cover window 20. The display panel 10 and the cover window 20 may be attached to each other by using a transparent adhesive member, such as an optically clear adhesive film.

The display panel 10 may display an image. The display panel 10 may include a substrate 100 and a pixel PX. The display panel 10 may include a display area DA and a peripheral area PA adjacent to the display area DA. The display area DA may include a center area CA, a first area A1, a second area A2, a corner area CNA, and an intermediate area MA. The center area CA, the first area A1, the second area A2, the corner area CNA, and the intermediate area MA, which are the display area DA, and the peripheral area PA may be defined on the substrate 100 of the display panel 10. In other words, the substrate 100 may include the center area CA, the first area A1, the second area A2, the corner area CNA, and the intermediate area MA, which are the display area DA, and the peripheral area PA adjacent to the display area DA.

The center area CA may be a flat area. The display panel 10 may be bent in the first area A1. The first area A1 may be adjacent to the center area CA in the first direction (e.g., the x direction or the −x direction). The first area A1 may be defined as an area bent from the center area CA on a cross section (e.g., an xz cross section) in the first direction (e.g., the x direction or the −x direction). The first area A1 may extend in the second direction (e.g., the y direction or the −y direction) and not be bent on a cross section (e.g., an yz cross section) in the second direction (e.g., the y direction or the −y direction). The first area A1 may be an area bent around an axis extending in the second direction (e.g., the y direction or the −y direction).

FIG. 2A illustrates that the first area A1 is bent while extending from the center area CA in the x direction and the first area A1 is bent while extending from the center area CA in the −x direction having a same curvature, but the disclosure is not limited thereto, and according to another embodiment, the first area A1 may be bent while extending from the center area CA in the x direction and the first area A1 may be bent while extending from the center area CA in the −x direction having different curvatures.

The display panel 10 may be bent in the second area A2. The second area A2 may be adjacent to the center area CA in the second direction (e.g., the y direction or the −y direction). The second area A2 may be defined as an area bent from the center area CA on the cross section (e.g., the yz cross section) in the second direction (e.g., the y direction or the −y direction). The second area A2 may extend in the first direction (e.g., the x direction or the −x direction). The second area A2 may not be bent on the cross section (e.g., the xz cross section) in the first direction (e.g., the x direction or the −x direction). The second area A2 may be an area bent around an axis extending in the first direction (e.g., the x direction or the −x direction). FIG. 2B illustrates that the second area A2 is bent while extending from the center area CA in the y direction and the second area A2 is bent while extending from the center area CA in the −y direction having a same curvature, but the disclosure is not limited thereto, and according to another embodiment, the second area A2 may be bent while extending from the center area CA in the y direction and the second area A2 may be bent while extending from the center area CA in the −y direction having different curvatures.

The display panel 10 may be bent in the corner area CNA. The corner area CNA may be an area arranged at the corner CN. According to an embodiment, the corner area CNA may be an area where the edge of the display device 1 in the first direction (e.g., the x direction or the −x direction) and the edge of the display device 1 in the second direction (e.g., the y direction or the −y direction) meet. In case that the first area A1 is bent while extending in the first direction (e.g., the x direction or the −x direction) and the second area A2 is bent while extending in the second direction (e.g., the y direction or the −y direction), at least a portion of the corner area CNA may be bent while extending in the first direction (e.g., the x direction or the −x direction) and bent while extending in the second direction (e.g., the y direction or the −y direction). In other words, at least a portion of the corner area CNA may be a multiple curvature area where multiple curvatures in multiple directions overlap each other. According to an embodiment, the display device 1 may have multiple corner areas CNA.

The intermediate area MA may be provided between the center area CA and the corner area CNA. The intermediate area MA may be located between the first area A1 and the corner area CNA. The intermediate area MA may be located between the second area A2 and the corner area CNA. According to an embodiment, the intermediate area MA may be bent. A driving circuit configured to provide an electric signal to the pixel PX and/or a power supply wire configured to provide power may be arranged in the intermediate area MA, and the pixel PX arranged in the intermediate area MA may overlap the driving circuit and/or the power supply wire.

The peripheral area PA may be arranged outside the center area CA. According to an embodiment, the peripheral area PA may be arranged outside the first area A1. The peripheral area PA may extend from the first area A1. According to an embodiment, the peripheral area PA extending from the first area A1 may be bent around an axis extending in the second direction (e.g., the y direction or the −y direction). According to an embodiment, the peripheral area PA may be arranged outside the second area A2. The peripheral area PA may extend from the second area A2. According to an embodiment, the peripheral area PA extending from the second area A2 may be bent around an axis extending in the first direction (e.g., the x direction or the −x direction). The pixel PX may not be arranged in the peripheral area PA. Accordingly, the peripheral area PA may be a non-display area where an image is not displayed. A driving circuit configured to provide an electric signal to the pixel PX and/or a power supply wire configured to provide power may be arranged in the peripheral area PA.

Referring to FIG. 2A, the first area A1, the intermediate area MA, and a portion of the corner area CNA may be bent with a first curvature radius R1. Referring to FIG. 2B, the second area A2, the intermediate area MA, and another portion of the corner area CNA may be bent with a second curvature radius R2. Referring to FIG. 2C, the intermediate area MA and another portion of the corner area CNA may be bent with a third curvature radius R3.

The pixel PX may be disposed on the substrate 100. According to an embodiment, the pixel PX may include a light-emitting diode and a pixel circuit electrically connected to the light-emitting diode. The display device may include multiple pixels PX, and the pixels PX may display an image by emitting light.

According to an embodiment, the pixels PX may be arranged in the center area CA, the first area A1, the second area A2, the corner area CNA, and the intermediate area MA, which are the display area DA. The display device 1 may be configured to display an image in the center area CA, the first area A1, the second area A2, the corner area CNA, and the intermediate area MA. Accordingly, a proportion of the display area DA that is an area of the display device 1, which displays an image, may increase. Also, the display device 1 may display an image at the corner CN, and thus, esthetic sense may be enhanced.

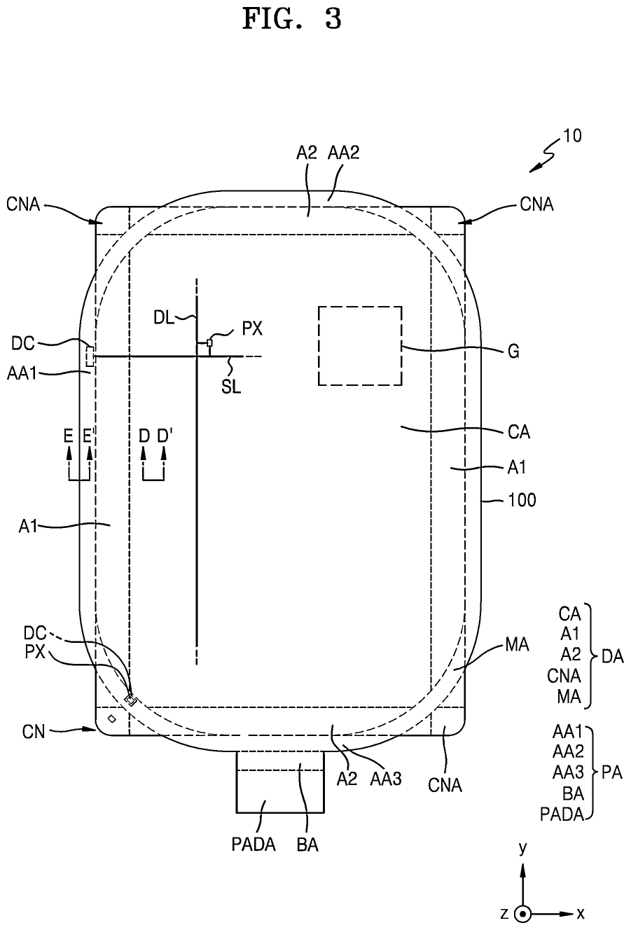

FIG. 3 is a plan view of the display panel 10 included in a display device, according to an embodiment. FIG. 3 is a plan view showing an unbent state of the display panel 10.

Referring to FIG. 3, the display panel 10 may display an image. The display panel 10 may include the substrate 100, the pixel PX, and a driving circuit DC. The substrate 100 may include the display area DA and the peripheral area PA outside the display area DA. The display area DA may include the center area CA, the first area A1, the second area A2, the corner area CNA, and the intermediate area MA. The center area CA may be a flat area. According to an embodiment, the display panel 10 may provide most of the image in the center area CA.

The first area A1 may extend from the center area CA in the first direction (e.g., the x direction or the −x direction). According to an embodiment, the first area A1 may be arranged between the center area CA and the peripheral area PA.

The second area A2 may extend from the center area CA in the second direction (e.g., the y direction or the −y direction). According to an embodiment, the second area A2 may be arranged between the center area CA and the peripheral area PA.

The corner area CNA may be an area arranged at the corner CN of the display panel 10. According to an embodiment, the corner area CNA may be an area where an edge of the display panel 10 in the first direction (e.g., the x direction or the −x direction) and an edge of the display panel 10 in the second direction (e.g., the y direction or the −y direction) meet.

The intermediate area MA may be provided between the center area CA and the corner area CNA. According to an embodiment, the intermediate area MA may be arranged between the first area A1 and the corner area CNA, and between the second area A2 and the corner area CNA. The driving circuit DC configured to provide an electric signal to the pixel PX and/or the power supply wire configured to provide power may be arranged in the intermediate area MA. The pixel PX arranged in the intermediate area MA may overlap the driving circuit DC and/or the power supply wire.

The peripheral area PA may be arranged outside the center area CA. The pixel PX may not be arranged in the peripheral area PA. Accordingly, the peripheral area PA may be a non-display area where an image is not displayed. The driving circuit DC configured to provide an electric signal to the pixel PX and/or the power supply wire configured to provide power may be arranged in the peripheral area PA. The peripheral area PA may include a first adjacent area AA1, a second adjacent area AA2, a third adjacent area AA3, a bending area BA, and a pad area PADA.

The first adjacent area AA1 may be arranged outside the first area A1. In other words, the first area A1 may be arranged between the first adjacent area AA1 and the center area CA. According to an embodiment, the first adjacent area AA1 may extend from the first area A1 in the first direction (e.g., the x direction or the −x direction). According to an embodiment, the driving circuit DC and/or the power supply wire may be arranged in the first adjacent area AA1.

The second adjacent area AA2 and the third adjacent area AA3 may be arranged outside the second area A2. In other words, the second area A2 may be provided between the second adjacent area AA2 and the center area CA. Also, the second area A2 may be provided between the third adjacent area AA3 and the center area CA. According to an embodiment, the second adjacent area AA2 and the third adjacent area AA3 may extend from the second area A2 in the second direction (e.g., the y direction or the −y direction).

The bending area BA may be arranged outside the third adjacent area AA3. In the bending area BA, the display panel 10 may be bendable in the rear direction of the substrate 100, and the pad area PADA may be located on a rear surface of the display panel 10, which is opposite to a top surface where an image is displayed. Accordingly, the area of the peripheral area PA shown to a user may be reduced.

The pad area PADA may be arranged outside the bending area BA. A pad (not shown) may be arranged in the pad area PADA. The display panel 10 may be configured to receive an electric signal and/or a power voltage through the pad.

At least one of the first area A1, the second area A2, the corner area CNA, and the intermediate area MA may be bent. For example, the first area A1 and a portion of the corner area CNA may be bent on the cross section (e.g., the xz cross section) in the first direction (e.g., the x direction or the −x direction). The first adjacent area AA1 extending from the first area A1 may be bent on the cross section (e.g., the xz cross section) in the first direction (e.g., the x direction or the −x direction). The second area A2 and another portion of the corner area CNA may be bent on the cross section (e.g., the yz cross section) in the second direction (e.g., the y direction or the −y direction).

The second adjacent area AA2 or the third adjacent area AA3 extending from the second area A2 may be bent on the cross section (e.g., the yz cross section) in the second direction (e.g., the y direction or the −y direction). Another portion of the corner area CNA may be bent on the cross section (e.g., the xz cross section) in the first direction (e.g., the x direction or the −x direction) and bent on the cross section (e.g., the yz cross section) in the second direction (e.g., the y direction or the −y direction).

The pixel PX and the driving circuit DC may be disposed on the substrate 100. The pixel PX may be arranged in at least one of the center area CA, the first area A1, the second area A2, the corner area CNA, and the intermediate area MA. According to an embodiment, the pixel PX may include a display element. According to an embodiment, the display element may be an organic light-emitting diode including an organic emission layer. According to another embodiment, the display element may be an inorganic light-emitting diode including an inorganic emission layer. The size of the light-emitting diode may be in micro-scale or nano-scale. According to an embodiment, the display element may be a quantum dot light-emitting diode including a quantum dot emission layer.

Each pixel PX may be configured to emit light of a color by using the display element. In the specification, a pixel may be a minimum unit for realizing an image and may be an emission area of a display element. In case that a light-emitting diode is employed as the display element, the emission area may be defined by an opening of a pixel-defining layer.

Each pixel PX may include a pixel circuit electrically connected to the display element. The driving circuit DC may provide a signal to the pixel circuit of the pixel PX. According to an embodiment, the driving circuit DC may be a scan driving circuit configured to provide a scan signal to the pixel PX through a scan line SL. According to another embodiment, the driving circuit DC may be an emission control driving circuit configured to provide an emission control signal to each pixel PX through an emission control line. According to another embodiment, the driving circuit DC may be a data driving circuit configured to provide a data signal to each pixel PX through a data line DL. According to an embodiment, the data driving circuit may be arranged in the third adjacent area AA3 or the pad area PADA. According to another embodiment, the data driving circuit may be arranged on a circuit board connected through the pad.

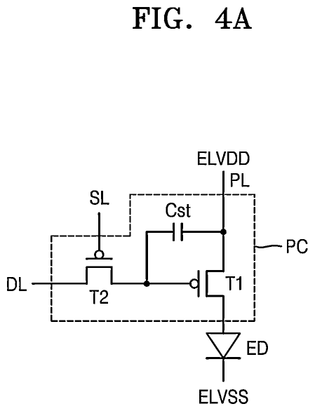

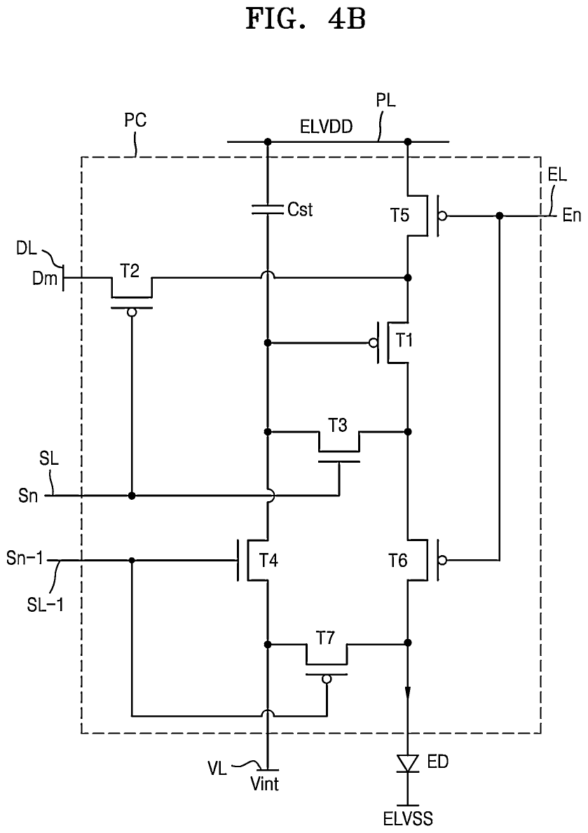

FIGS. 4A and 4B are schematic diagrams of an equivalent circuit of a pixel included in a display device, according to embodiments.

Referring to FIG. 4A, a pixel may include a light-emitting diode ED as a display element and a pixel circuit PC electrically connected to the light-emitting diode ED. The pixel circuit PC may include a driving transistor T1, a switching transistor T2, and a storage capacitor Cst. According to an embodiment, the light-emitting diode ED may be configured to emit red, green, or blue light or emit red, green, blue, or white light.

The switching transistor T2 may be connected to the scan line SL and the data line DL, and may be configured to transmit, to the driving transistor T1, a data signal input from the data line DL according to a scan signal input from the scan line SL.

The storage capacitor Cst may be connected to the switching transistor T2 and a driving voltage line PL, and may be configured to store a voltage corresponding to a difference between a voltage received from the switching transistor T2 and a first power voltage ELVDD supplied from the driving voltage line PL.

The driving transistor T1 may be connected to the driving voltage line PL and the storage capacitor Cst, and may be configured to control a driving current flowing to the light-emitting diode ED from the driving voltage line PL in response to a voltage value stored in the storage capacitor Cst. The light-emitting diode ED may emit light of a luminance according to the driving current. An opposing electrode of the light-emitting diode ED may receive a second power voltage ELVSS.

FIG. 4A illustrates that the pixel circuit PC includes two transistors and one storage capacitor, but the disclosure is not limited thereto, and in another embodiment, the pixel circuit PC may include more than two transistors.

Referring to FIG. 4B, the pixel circuit PC may include the driving transistor T1, the switching transistor T2, a compensation transistor T3, a first initialization transistor T4, an operation control transistor T5, an emission control transistor T6, and a second initialization transistor T7.

A drain electrode of the driving transistor T1 may be electrically connected to the light-emitting diode ED through the emission control transistor T6. The driving transistor T1 may supply a driving current to the light-emitting diode ED by receiving a data signal Dm according to a switching operation of the switching transistor T2.

A gate electrode of the switching transistor T2 may be connected to the scan line SL and a source electrode of the switching transistor T2 may be connected to the data line DL. A drain electrode of the switching transistor T2 may be connected to a source electrode of the driving transistor T1 and connected to the driving voltage line PL through the operation control transistor T5.

The switching transistor T2 may be turned on according to a scan signal Sn received through the scan line SL to perform a switching operation of transmitting the data signal Dm transmitted to the data line DL, to the source electrode of the driving transistor T1.

A gate electrode of the compensation transistor T3 may be connected to the scan line SL. A source electrode of the compensation transistor T3 may be connected to the drain electrode of the driving transistor T1, and connected to a pixel electrode (e.g., an anode) of the light-emitting diode ED through the emission control transistor T6. A drain electrode of the compensation transistor T3 may be connected to an electrode of the storage capacitor Cst, a source electrode of the first initialization transistor T4, and the gate electrode of the driving transistor T1. The compensation transistor T3 may be turned on according to the scan signal Sn received through the scan line SL, thereby diode-connecting the driving transistor T1.

A gate electrode of the first initialization transistor T4 may be connected to a previous scan line SL-1. A drain electrode of the first initialization transistor T4 may be connected to an initialization voltage line VL. A source electrode of the first initialization transistor T4 may be connected to an electrode of the storage capacitor Cst, the drain electrode of the compensation transistor T3, and the gate electrode of the driving transistor T1. The first initialization transistor T4 may be turned on according to a previous scan signal Sn-1 received through the previous scan line SL-1 to transmit an initialization voltage Vint to the gate electrode of the driving transistor T1, thereby performing an initialization operation of initializing a voltage of the gate electrode of the driving transistor T1.

A gate electrode of the operation control transistor T5 may be connected to an emission control line EL. A source electrode of the operation control transistor T5 may be connected to the driving voltage line PL. A drain electrode of the operation control transistor T5 may be connected to the source electrode of the driving transistor T1 and the drain electrode of the switching transistor T2.

A gate electrode of the emission control transistor T6 may be connected to the emission control line EL. A source electrode of the emission control transistor T6 may be connected to the drain electrode of the driving transistor T1 and the source electrode of the compensation transistor T3. A drain electrode of the emission control transistor T6 may be electrically connected to the pixel electrode of the light-emitting diode ED. The operation control transistor T5 and the emission control transistor T6 may be simultaneously turned on according to an emission control signal En received via the emission control line EL, and thus a driving current may flow to the light-emitting diode ED.

A gate electrode of the second initialization transistor T7 may be connected to the previous scan line SL-1. A source electrode of the second initialization transistor T7 may be connected to the pixel electrode of the light-emitting diode ED. A drain electrode of the second initialization transistor T7 may be connected to the initialization voltage line VL. The second initialization transistor T7 may be turned on according to the previous scan signal Sn-1 received through the previous scan line SL-1 to initialize the pixel electrode of the light-emitting diode ED.

FIG. 4B illustrates that the first initialization transistor T4 and the second initialization transistor T7 are both connected to the previous scan line SL-1, but the disclosure is not limited thereto, and according to another embodiment, the first initialization transistor T4 and the second initialization transistor T7 may be connected to the previous scan line SL-1 and a next scan line (not illustrated), respectively, and the first initialization transistor T4 and the second initialization transistor T7 may operate according to the previous scan signal Sn-1 and a next scan signal, respectively.

Also, FIG. 4B illustrates that the first initialization transistor T4 and the second initialization transistor T7 are both connected to the initialization voltage line VL, but the disclosure is not limited thereto, and according to another embodiment, the first initialization transistor T4 and the second initialization transistor T7 may be connected to different initialization voltage lines. For example, the first initialization transistor T4 may be connected to a first initialization voltage line configured to transmit a first initialization voltage, and the second initialization transistor T7 may be connected to a second initialization voltage line configured to transmit a second initialization voltage. The first initialization voltage and the second initialization voltage may be different from each other.

An electrode of the storage capacitor Cst may be connected to the driving voltage line PL. Another electrode of the storage capacitor Cst may be connected to the gate electrode of the driving transistor T1, the drain electrode of the compensation transistor T3, and the source electrode of the first initialization transistor T4 together.

An opposing electrode (e.g., a cathode) of the light-emitting diode ED may receive the second power voltage ELVSS. The light-emitting diode ED may emit light by receiving the driving current from the driving transistor T1.

According to embodiments, some of the transistors T1 to T7 may be n-channel transistors and the remaining ones may be p-channel transistors. According to an embodiment, the compensation transistor T3 and the first initialization transistor T4 may be n-channel transistors and the remaining transistors T1, T2, T5, T6, and T7 may be p-channel transistors.

A transistor including a silicon semiconductor layer has high electron mobility and excellent reliability. Accordingly, the driving transistor T1 directly affecting brightness of an organic light-emitting diode (OLED) may include a silicon semiconductor layer, thereby realizing a high-resolution display device.

A transistor including an oxide semiconductor layer has a low off-current and is low-frequency operable. Accordingly, at least one of the remaining transistors T2 to T7 excluding the driving transistor T1 may include an oxide semiconductor layer, thereby reducing power consumption of a display device.

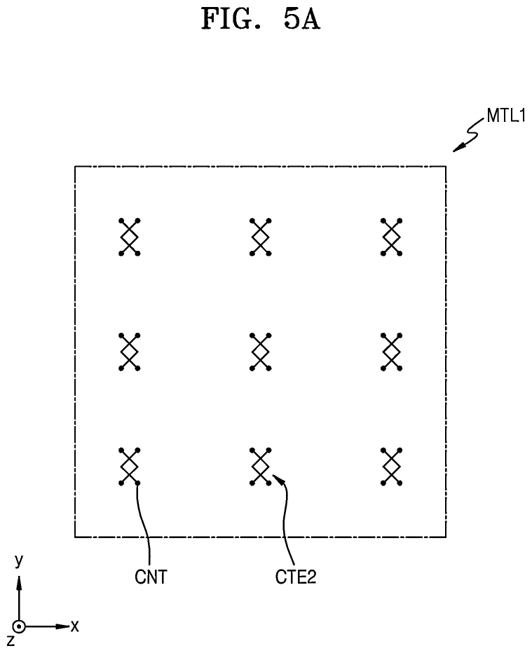

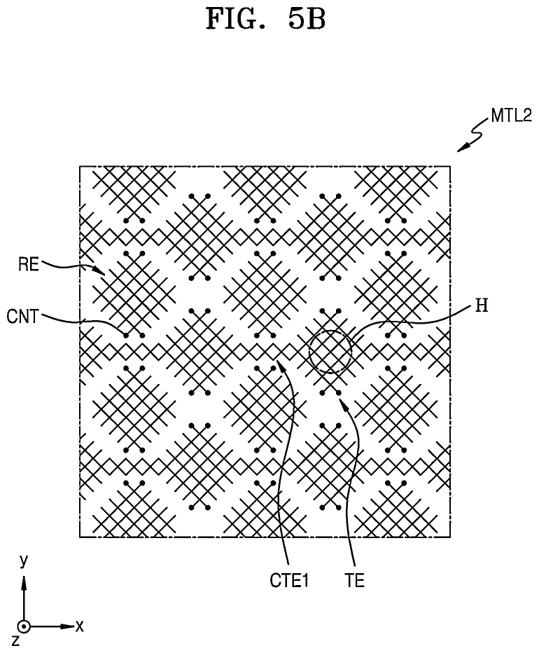

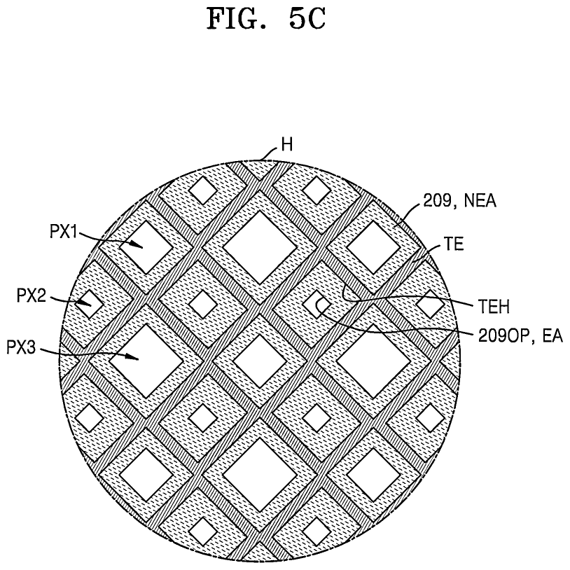

FIGS. 5A and 5B are each a plan view of a portion of region G of the display panel 10 of FIG. 3, and FIG. 5C is an enlarged plan view of region H illustrated in FIG. 5B. FIG. 5A schematically illustrates a first touch conductive layer MTL1 of the display panel 10 and FIG. 5B schematically illustrates a second touch conductive layer MTL2 of the display panel 10.

Referring to FIGS. 5A and 5B, the display panel 10 may include a first touch conductive layer MTL1 and a second touch conductive layer MTL2 on the first touch conductive layer MTL1, which form a touch sensor. At least one insulating layer may be arranged between the first touch conductive layer MTL1 and the second touch conductive layer MTL2.

Each of the first touch conductive layer MTL1 and the second touch conductive layer MTL2 may have a single layer structure or a stacked multilayer structure. A conductive layer of the single layer structure may include a metal layer or a transparent conductive layer. The metal layer may include molybdenum (Mo), silver (Ag), titanium (Ti), copper (Cu), aluminum (Al), or an alloy thereof. The transparent conductive layer may include a transparent conductive oxide, such as indium tin oxide (ITO), indium zinc oxide (IZO), zinc oxide (ZnO), or indium tin zinc oxide (ITZO). The transparent conductive layer may include a conductive polymer, such as poly(3,4-ethylenedioxythiophene) (PEDOT), metal nanowire, or graphene.

A conductive layer of the multilayer structure may have, for example, a three-layer structure of Ti/Al/Ti. The conductive layer of the multilayer structure may include at least one metal layer and at least one transparent conductive layer.

Each of the first touch conductive layer MTL1 and the second touch conductive layer MTL2 may include multiple conductive patterns. For example, the first touch conductive layer MTL1 may include second connecting electrodes CTE2 and the second touch conductive layer MTL2 may include body portions of driving electrodes TE and sensing electrodes RE.

The driving electrodes TE may extend in the first direction (e.g., the x direction or −x direction) and spaced apart from each other in the second direction (e.g., the y direction or −y direction). The driving electrodes TE may include body portions and first connecting electrodes CTE1 connecting the body portions adjacent in the first direction (e.g., the x direction or the −x direction) to each other. According to an embodiment, the first connecting electrodes CTE1 and the body portions of the driving electrodes TE may be integrally with each other.

The sensing electrodes RE may include the second connecting electrodes CTE2 arranged in the first touch conductive layer MTL1, and the body portions arranged in the second touch conductive layer MTL2. The second connecting electrodes CTE2 may connect the body portions of the sensing electrodes RE adjacent in the second direction (e.g., the y direction or the −y direction), through a contact hole CNT.

In a plan view, the first connecting electrodes CTE1 and the second connecting electrodes CTE2 may be arranged to cross each other. At least one insulating layer may be provided between the first connecting electrode CTE1 and the second connecting electrode CTE2, and thus, the first connecting electrode CTE1 and the second connecting electrode CTE2, which overlap each other in a plan view, may form a type of capacitor. The touch sensor may sense an external input through a capacitance change of such a capacitor.

The driving electrodes TE and the sensing electrodes RE may have a mesh (or grid or lattice) pattern in a plan view. The mesh pattern may be formed by mesh lines extending in a third direction and a fourth direction respectively intersecting the first direction (x direction) and the second direction (y direction) intersecting each other. Accordingly, the driving electrodes TE and the sensing electrodes RE may include multiple electrode holes.

Referring to FIGS. 5A and 5B, the second connecting electrode CTE2 may be included in the first touch conductive layer MTL1, and the body portions of the driving electrode TE and sensing electrode RE may be included in the second touch conductive layer MTL2, but the disclosure is not limited thereto.

According to another embodiment, the first touch conductive layer MTL1 may include the body portions of the driving electrode TE and sensing electrode RE, and the second touch conductive layer MTL2 may include the second connecting electrodes CTE2. According to another embodiment, various modifications are possible, for example, the first touch conductive layer MTL1 may include the driving electrodes TE, and the second touch conductive layer MTL2 may include the sensing electrodes RE.

Referring to FIG. 5C, the display panel 10 may include first pixels PX1, second pixels PX2, and third pixels PX3. The first pixel PX1 may include a light-emitting diode emitting red light. The second pixel PX2 may include a light-emitting diode emitting green light. The third pixel PX3 may include a light-emitting diode emitting blue light. In FIG. 5C, the first pixel PX1, the second pixel PX2, and the third pixel PX3 may each indicate an emission area EA of the light-emitting diode included in each pixel.

In FIG. 5C, the first pixels PX1, the second pixels PX2, and the third pixels PX3 may be arranged in a PenTile™ Matrix, but the disclosure is not limited thereto. The first pixels PX1, the second pixels PX2, and the third pixels PX3 may be arranged in another pattern, for example, in a stripe or in a Diamond Pixel™.

The emission area EA of the light-emitting diode may be defined by a pixel opening 2090P defined by a pixel-defining layer 209. A non-emission area NEA may overlap the pixel-defining layer 209 in a plan view and may be arranged between adjacent emission areas EA. The areas of emission areas EA may be different for each pixel. Accordingly, the areas of pixel openings 2090P defined by the pixel-defining layer 209 may also be different from each other. For example, the emission area EA of the first pixel PX1 may be greater than the emission area EA of the second pixel PX2 and less than the emission area EA of the third pixel PX3 in a plan view. However, the disclosure is not limited thereto.

The driving electrode TE may have a mesh pattern as mesh lines extending in the third direction and the fourth direction respectively intersecting the first direction (x direction) and the second direction (y direction) intersecting each other. The mesh lines of the driving electrode TE may define multiple electrode holes TEH. In other words, the driving electrodes TE may define the electrode holes TEH. The electrode holes TEH may respectively overlap multiple light-emitting diodes in a plan view. The mesh lines of the driving electrode TE may overlap the non-emission area NEA in a plan view.

FIG. 5C has been described based on the driving electrode TE, but a similar or same structure may be applied to the sensing electrode RE, the first connecting electrode CTE1, and the second connecting electrode CTE2.

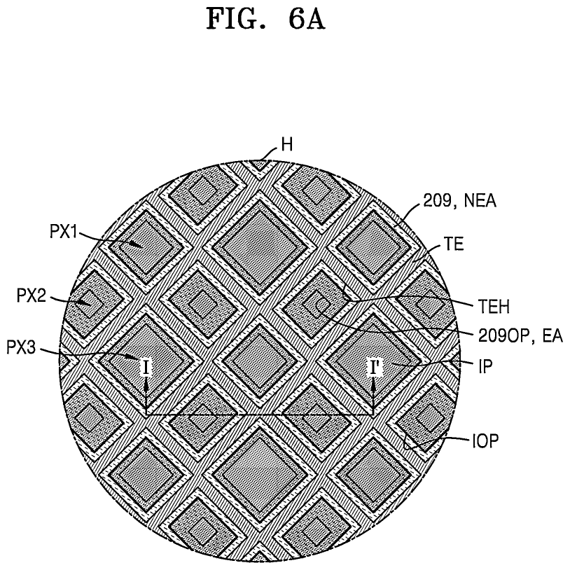

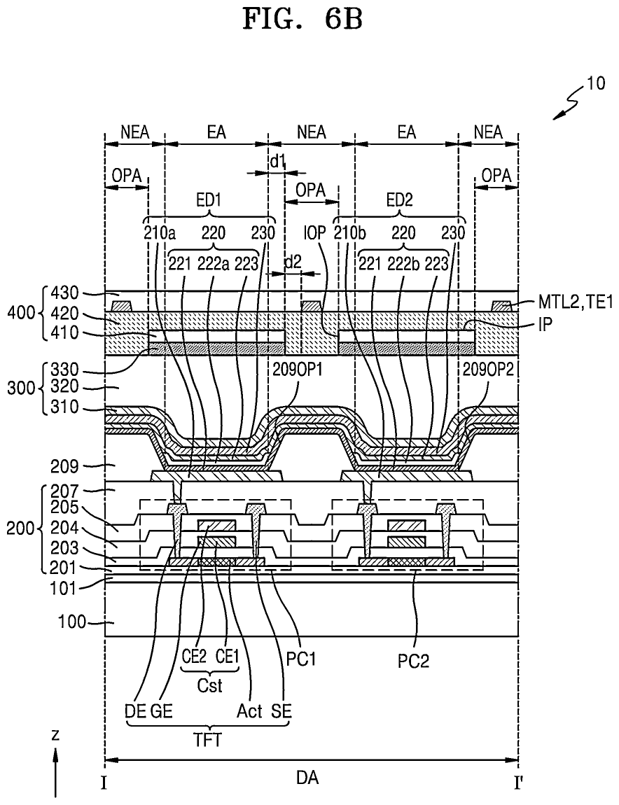

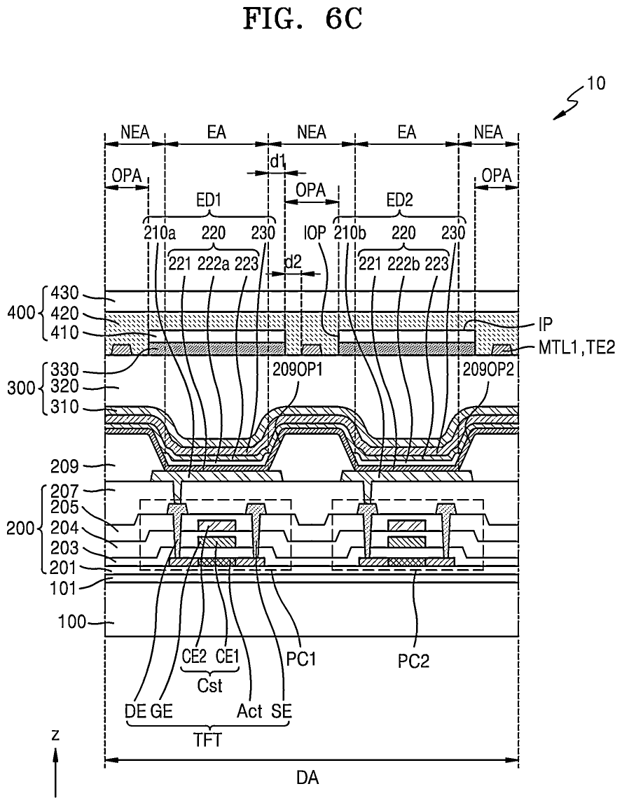

FIG. 6A is a plan view of a portion of a display panel, according to an embodiment, and FIGS. 6B and 6C are schematic cross-sectional views of the display panel of FIG. 6A. FIG. 6B is a schematic cross-sectional view of the display panel taken along line I-I′ of FIG. 6A. FIG. 6C is a schematic cross-sectional view of a region where a second touch electrode TE2 is arranged, to describe an arrangement of the first touch conductive layer MTL1.

Referring to FIG. 6A, the display panel may include multiple inorganic patterns IP that are spaced apart from each other. The inorganic patterns IP may be a single layer or multilayer including an inorganic insulating material, such as silicon oxide, silicon nitride, and/or silicon oxynitride.

The inorganic patterns IP may respectively cover the emission areas EA of the light-emitting diodes. In a plan view, the emission area EA of the light-emitting diode may be located inside the corresponding inorganic pattern IP.

The inorganic patterns IP may be spaced apart from each other and define a first opening IOP located between the inorganic patterns IP. The first opening IOP may have a shape approximately corresponding to a shape of the pixel-defining layer 209 in a plan view. The first opening IOP may overlap a portion of the pixel-defining layer 209 and not overlap the pixel opening 2090P in a plan view.

In a plan view, the inorganic patterns IP may be respectively located inside the electrode holes TEH. In other words, the inorganic patterns IP may be spaced apart from the mesh lines of the driving electrode TE. The first opening IOP may have a shape approximately corresponding to a shape of the driving electrode TE in a plan view. The first opening IOP may overlap the driving electrode TE in a plan view.

Referring to FIGS. 6B and 6C, a pixel circuit layer 200, first and second light-emitting diodes ED1 and ED2, an encapsulation layer 300, and a touch sensor layer 400 may be sequentially stacked on the display area DA of the substrate 100. First and second pixel circuits PC1 and PC2, which are electrically connected to the first and second light-emitting diodes ED1 and ED2, may be arranged in the pixel circuit layer 200.

The substrate 100 may include an insulating material, such as glass, quartz, a polymer resin, or the like. The substrate 100 may be a rigid substrate or a flexible substrate capable of being bent, folded, or rolled.

A buffer layer 201 may be arranged on the substrate 100 to reduce or prevent penetration of impurities, moisture, or external air from a lower portion of the substrate 100, and provide a flat surface to a semiconductor layer Act. The buffer layer 201 may include an inorganic material, such as an oxide or a nitride, an organic material, or an organic and inorganic complex, and may have a single layer or multiplayer structure of an inorganic material and an organic material.

A barrier layer 101 configured to prevent penetration of external air may be further provided between the substrate 100 and the buffer layer 201. The barrier layer 101 and the buffer layer 201 may be a single layer or multilayer including an inorganic insulating material, such as silicon oxide, silicon nitride, and/or silicon oxynitride.

The first pixel circuit PC1 and the second pixel circuit PC2, which include a thin-film transistor TFT and the storage capacitor Cst, may be disposed on the buffer layer 201. The first pixel circuit PC1 and the second pixel circuit PC2 may have a same or similar structure. Hereinafter, the first pixel circuit PC1 will be described.

The thin-film transistor TFT may correspond to the driving transistor T1 described with reference to FIG. 4A. The thin-film transistor TFT may include a semiconductor layer Act, a gate electrode GE, a drain electrode DE, and a source electrode SE.

The semiconductor layer Act may be disposed on the buffer layer 201 and may include polysilicon. According to another embodiment, the semiconductor layer Act may include amorphous silicon. According to another embodiment, the semiconductor layer Act may include an oxide of at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer Act may include a channel region, and a source region and a drain region, where impurities are doped. The source region and the drain region may be arranged on a side of the channel region.

A first gate insulating layer 203 may be provided to cover the semiconductor layer Act. The first gate insulating layer 203 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first gate insulating layer 203 may be a single layer or multilayer including the inorganic insulating material described above.

The gate electrode GE may be arranged on the first gate insulating layer 203 and overlap the semiconductor layer Act in a plan view. The gate electrode GE may include a metal material, such as Mo, Al, Cu, or Ti, and may be a single layer or multilayer. For example, the gate electrode GE may be a single layer of Mo.

A second gate insulating layer 204 may be provided to cover the gate electrode GE. The second gate insulating layer 204 may include an inorganic insulating material, such as SiO₂, SiNₓ, SiON, Al₂O₃, TiO₂, Ta₂O₅, HfO₂, or ZnO₂. The second gate insulating layer 204 may be a single layer or multilayer including the inorganic insulating material described above.

A second electrode CE2 of the storage capacitor Cst may be disposed on the second gate insulating layer 204. The second electrode CE2 may overlap the gate electrode GE in a plan view. The gate electrode GE and the second electrode CE2 may overlap each other in a plan view, and the second gate insulating layer 204 may be interposed between the gate electrode GE and the second electrode CE2, thereby forming the storage capacitor Cst. In other words, the gate electrode GE may operate as a first electrode CE1 of the storage capacitor Cst.

The second electrode CE2 may include a metal material, such as Mo, Al, Cu, or Ti, and may be a single layer or multilayer.

An interlayer insulating layer 205 may be provided to cover the second electrode CE2. The interlayer insulating layer 205 may be a single layer or multilayer including an inorganic insulating material, such as silicon oxide, silicon nitride, and/or silicon oxynitride.

The source electrode SE and the drain electrode DE may be disposed on the interlayer insulating layer 205. The source electrode SE and the drain electrode DE may include a metal material, such as Mo, Al, Cu, or Ti, and may be a single layer or multilayer. For example, the source electrode SE and the drain electrode DE may have a multiplayer structure of a Ti layer, an Al layer, and a Ti layer. According to another embodiment, the source electrode SE or the drain electrode DE may be omitted.

A planarization insulating layer 207 may be provided to cover the source electrode SE and drain electrode DE. The planarization insulating layer 207 may provide a flat base surface to the first light-emitting diode ED1 and the second light-emitting diode ED2, which are disposed in planarization insulating layer 207.

The planarization insulating layer 207 may include an organic material or an inorganic material, and may have a single layer structure or a multilayer structure. The planarization insulating layer 207 may include a general-purpose polymer, such as benzocyclobutene (BCB), polyimide, hexamethyldisiloxane (HMDSO), polymethylmethacrylate (PMMA), or polystyrene, a polymer derivative having a phenol-based group, an acryl-based polymer, an imide-based polymer, an arylether-based polymer, an amide-based polymer, a fluorine-based polymer, a p-xylene-based polymer, or a vinyl alcohol-based polymer. The planarization insulating layer 207 may include an inorganic insulating material, such as SiO₂, SiNₓ, SiON, Al₂O₃, TiO₂, Ta₂O₅, HfO₂, or ZnO₂. When forming the planarization insulating layer 207, to provide a flat top surface after forming a layer, mechanical polishing may be performed on the top surface of the layer.

The first light-emitting diode ED1 and the second light-emitting diode ED2 may be disposed on the planarization insulating layer 207. The first light-emitting diode ED1 may be electrically connected to the first pixel circuit PC1, and the second light-emitting diode ED2 may be electrically connected to the second pixel circuit PC2. The first light-emitting diode ED1 may include a first pixel electrode 210a, an intermediate layer 220, and an opposing electrode 230, and the second light-emitting diode ED2 may include a second pixel electrode 210b, the intermediate layer 220, and the opposing electrode 230. The first light-emitting diode ED1 and the second light-emitting diode ED2 may have a substantially same or similar structure. Hereinafter, the first light-emitting diode ED1 will be described.

The planarization insulating layer 207 may include a via hole for exposing one of the source electrode SE and the drain electrode DE of the thin-film transistor TFT, and the first pixel electrode 210a may be in contact with the source electrode SE or the drain electrode DE through the via hole to be electrically connected to the thin-film transistor TFT of the first pixel circuit PC1.

FIG. 6B schematically illustrates an embodiment that the planarization insulating layer 207 has a single layer structure, but the disclosure is not limited thereto, and according to an embodiment, the planarization insulating layer 207 may have a multilayer structure in which multiple organic material layers are stacked on each other. Connecting electrodes may be arranged between the organic material layers, and the first pixel electrode 210a may be in contact with the source electrode SE or the drain electrode DE through the connecting electrode to be electrically connected to the first pixel circuit PC1.

The first pixel electrode 210a and the second pixel electrode 210b may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO).

The first pixel electrode 210a and the second pixel electrode 210b may include a reflective film including Ag, Mg, Al, platinum (Pt), palladium (Pd), gold (Au), nickel (Ni), neodymium (Nd), iridium (Ir), Cr, or a compound thereof. For example, the first pixel electrode 210a and the second pixel electrode 210b may have a structure in which a film including ITO, IZO, ZnO, or In₂O₃ is disposed on/below the reflective film, and the first pixel electrode 210a and the second pixel electrode 210b may have a stack structure of ITO/Ag/ITO.

The pixel-defining layer 209 may include a first pixel opening 2090P1 and a second pixel opening 2090P2, which respectively cover edges of the first pixel electrode 210a and the second pixel electrode 210b on the planarization insulating layer 207 and respectively expose center portions of the first pixel electrode 210a and the second pixel electrode 210b. The emission area EA of the first light-emitting diode ED1, i.e., the size and shape of a pixel, may be defined by the first pixel opening 2090P1, and the emission area EA of the second light-emitting diode ED2, i.e., the size and shape of a pixel, may be defined by the second pixel opening 2090P2.

The pixel-defining layer 209 may increase a distance between the opposing electrode 230 and the edge of each of the first pixel electrode 210a and the second pixel electrode 210b, thereby preventing occurrence of arc at the edge of each of the first pixel electrode 210a and the second pixel electrode 210b. The pixel-defining layer 209 may be formed through a method, such as spin coating, using an organic insulating material, such as polyimide, polyamide, an acryl resin, benzo cyclobutene, HMDSO, or a phenol resin.

The pixel-defining layer 209 may be formed in black. The pixel-defining layer 209 may include a light-blocking material and be provided in black. The light-blocking material may include a resin or paste including carbon black, carbon nanotubes, or black dyes, metal particles such as Ni, Al, Mo, or an alloy thereof, metal oxide particles (for example, chromium oxide), or metal nitride particles (for example, chromium nitride). In case that the pixel-defining layer 209 includes a light-blocking material, external light reflection caused by metal structures arranged at a lower portion of the pixel-defining layer 209 may be reduced.

The intermediate layer 220 may be provided between the opposing electrode 230, and the first pixel electrode 210a and the second pixel electrode 210b. The intermediate layer 220 may include a first emission layer 222a formed to correspond to the first pixel electrode 210a, and a second emission layer 222b formed to correspond to the second pixel electrode 210b. For example, the first emission layer 222a may be arranged inside the first pixel opening 2090P1 and the second emission layer 222b may be arranged inside the second pixel opening 2090P2.

The first emission layer 222a and the second emission layer 222b may include a high-molecular weight or a low-molecular weight material, and emit red, green, blue, or white light.

A first functional layer 221 and a second functional layer 223 may be disposed below and/or on each of the first emission layer 222a and the second emission layer 222b. According to an embodiment, unlike the first emission layer 222a and the second emission layer 222b being patterned for each pixel, the first functional layer 221 and the second functional layer 223 may be integrally provided throughout the display area DA.

The first functional layer 221 may be a single layer or multilayer. For example, in case that the first functional layer 221 is formed of a high-molecular weight material, the first functional layer 221 may be a hole transport layer having a single layer structure and may include poly-(3,4)-ethylene-dihydroxy thiophene (PEDOT) or polyaniline (PANI). In case that the first functional layer 221 is formed of a low-molecular weight material, the first functional layer 221 may include a hole injection layer and the hole transport layer.

The second functional layer 223 may be optional. For example, in case that the first functional layer 221 and an emission layer 222 are formed of a high-molecular weight material, the second functional layer 223 may be formed. The second functional layer 223 may be a single layer or multilayer. The second functional layer 223 may include an electron transport layer and/or an electron injection layer. According to embodiments, at least one of the hole injection layer, the hole transport layer, the electron transport layer, and the electron injection layer may be omitted.

The opposing electrode 230 may include a conductive material with a relatively low work function. For example, the opposing electrode 230 may include a (semi-)transparent layer including Ag, Mg, Al, Ni, Cr, Li, Ca, or an alloy thereof. The opposing electrode 230 may further include a layer including ITO, IZO, ZnO, or In₂O₃, on the (semi-)transparent layer including such a material. According to an embodiment, the opposing electrode 230 may include Ag and Mg.

According to an embodiment, a capping layer (not shown) may be further disposed on the opposing electrode 230. The capping layer may enhance light-emitting efficiency of the first light-emitting diode ED1 according to the principle of constructive interference. The capping layer may be an organic capping layer including an organic material, an inorganic capping layer including an inorganic material, or a complex capping layer including an organic material and an inorganic material.

The encapsulation layer 300 may be disposed on the first light-emitting diode ED1 and the second light-emitting diode ED2. According to an embodiment, the encapsulation layer 300 may include at least one inorganic encapsulation layer and at least one organic encapsulation layer. For example, the encapsulation layer 300 may include first and second inorganic encapsulation layers 310 and 330, and an organic encapsulation layer 320 between the first and second inorganic encapsulation layers 310 and 330.

The first inorganic encapsulation layer 310 may be disposed on the opposing electrode 230. The first inorganic encapsulation layer 310 may be a single layer or multilayer including an inorganic insulating material, such as silicon oxide, silicon nitride, and/or silicon oxynitride. According to an embodiment, the first inorganic encapsulation layer 310 may include a silicon nitride layer. The silicon nitride layer has a dense structure, and thus, in case that the first inorganic encapsulation layer 310 includes a silicon nitride layer, the first light-emitting diode ED1 and the second light-emitting diode ED2 may be sufficiently prevented from being damaged due to a manufacture process performed after the first light-emitting diode ED1 and the second light-emitting diode ED2 are formed. The first inorganic encapsulation layer 310 may be formed through a chemical vapor deposition.

The organic encapsulation layer 320 may be disposed on the first inorganic encapsulation layer 310. The organic encapsulation layer 320 may include polyethylene terephthalate, polyethylene naphthalate, polycarbonate, polyimide, polyethylene sulfonate, polyoxymethylene, polyarylate, HMDSO, acryl-based resin, or a combination thereof.

The second inorganic encapsulation layer 330 may be disposed on the organic encapsulation layer 320. The second inorganic encapsulation layer 330 may be a single layer or multilayer including an inorganic insulating material, such as silicon oxide, silicon nitride, and/or silicon oxynitride. The second inorganic encapsulation layer 330 may be formed through a chemical vapor deposition.

The second inorganic encapsulation layer 330 may form the inorganic patterns IP covering each of the emission area EA of the first light-emitting diode ED1 and the emission area EA of the second light-emitting diode ED2. For example, as schematically illustrated in FIG. 6B, the inorganic patterns IP may be formed in a double layer of the second inorganic encapsulation layer 330 (first inorganic layer) and a first touch insulating layer 410 (second inorganic layer) described below. According to another embodiment, the inorganic patterns IP may be formed as a single layer of the second inorganic encapsulation layer 330.

The touch sensor layer 400 may have a multilayer structure. The touch sensor layer 400 may include the sensing electrode RE (see FIG. 5B), a sensing signal line connected to the sensing electrode RE, the driving electrode TE, a driving signal line connected to the driving electrode TE, and at least one insulating layer. The touch sensor included in the touch sensor layer 400 may sense an external input through, for example, capacitance.

The touch sensor layer 400 may include the first touch insulating layer 410, the first touch conductive layer MTL1, a second touch insulating layer 420, the second touch conductive layer MTL2, and a third touch insulating layer 430.

The first touch insulating layer 410 may be disposed on (e.g., disposed directly on) the encapsulation layer 300. The first touch insulating layer 410 may be a single layer or multilayer including an inorganic insulating material, such as silicon oxide, silicon nitride, and/or silicon oxynitride. The first touch insulating layer 410 may be a layer formed throughout the substrate 100 to cover an outer boundary of the second inorganic encapsulation layer 330 in the peripheral area PA (see FIG. 1) to enhance adhesion of the second inorganic encapsulation layer 330.

As described above, the first touch insulating layer 410 may form the inorganic pattern IP covering each of the emission area EA of the first light-emitting diode ED1 and the emission area EA of the second light-emitting diode ED2. The width (or the area) of the inorganic pattern IP may be greater than the width (or the area) of the corresponding emission area EA. For example, a boundary of the inorganic pattern IP corresponding to the emission area EA of the first light-emitting diode ED1 may be spaced apart from a boundary of the first pixel opening 2090P1 by a first distance d1. The first distance d1 may be about 2 um.

The first opening IOP may be defined between the neighboring inorganic patterns IP. The first opening IOP may be an opening penetrating the first touch insulating layer 410 and the second inorganic encapsulation layer 330. A first opening area OPA where the first opening IOP is arranged may overlap the non-emission area NEA in a plan view. In other words, the first opening IOP may not overlap the first pixel opening 2090P1 and the second pixel opening 2090P2 in a plan view.

In case that a portion (e.g., an edge region) of the display panel 10 is bent in the rear direction of the substrate 100 to have a specific curvature, the light-emitting diodes may be damaged as stress is concentrated on some region. According to an embodiment, an inorganic layer on the organic encapsulation layer 320, for example, the second inorganic encapsulation layer 330 and the first touch insulating layer 410, are patterned to form the inorganic patterns IP spaced apart from each other, and thus, elongation of a top surface of the display panel 10 may be increased, thereby reducing or preventing the stress from being concentrated on a region. Accordingly, reliability of the display panel 10 may be increased.

According to an embodiment, the inorganic patterns IP may be formed only in a portion (e.g., the edge region) of the display panel 10. In other words, the second inorganic encapsulation layer 330 and/or the first touch insulating layer 410 may be not patterned but may be integrally formed in a flat region (e.g., the center area CA, see FIG. 1) of the display panel 10.

According to another embodiment, the inorganic patterns IP may be formed throughout the display area DA (see FIG. 1) of the display panel 10.

The first touch conductive layer MTL1 and the second touch conductive layer MTL2 may be disposed on the first touch insulating layer 410. The second touch insulating layer 420 may be arranged between the first touch conductive layer MTL1 and the second touch conductive layer MTL2.

Each of the first touch conductive layer MTL1 and the second touch conductive layer MTL2 may have a single layer structure or a stacked multilayer structure. A conductive layer of the single layer structure may include a metal layer or a transparent conductive layer. The metal layer may include Mo, Ag, Ti, Cu, Al, or an alloy thereof. The transparent conductive layer may include a transparent conductive oxide, such as ITO, IZO, ZnO, or ITZO. The transparent conductive layer may include a conductive polymer such as PEDOT, metal nanowire, or graphene.

The first touch conductive layer MTL1 may include multiple conductive patterns. The second touch conductive layer MTL2 may include multiple conductive patterns. In this regard, FIGS. 6B and 6C schematically illustrate the first touch conductive layer MTL1 including the second touch electrode TE2, and the second touch conductive layer MTL2 including a first touch electrode TE1.

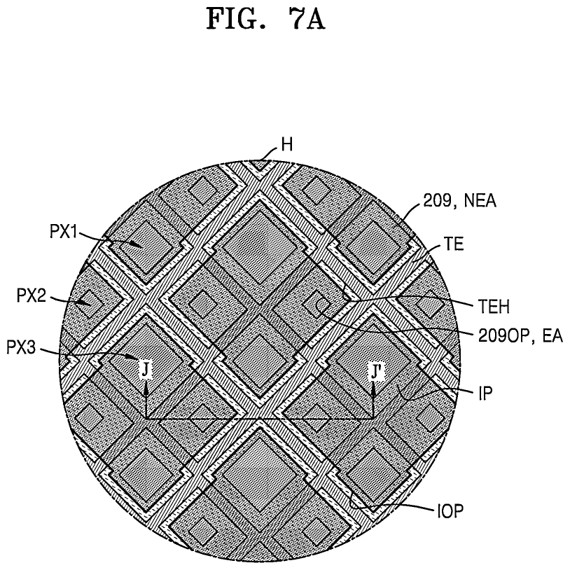

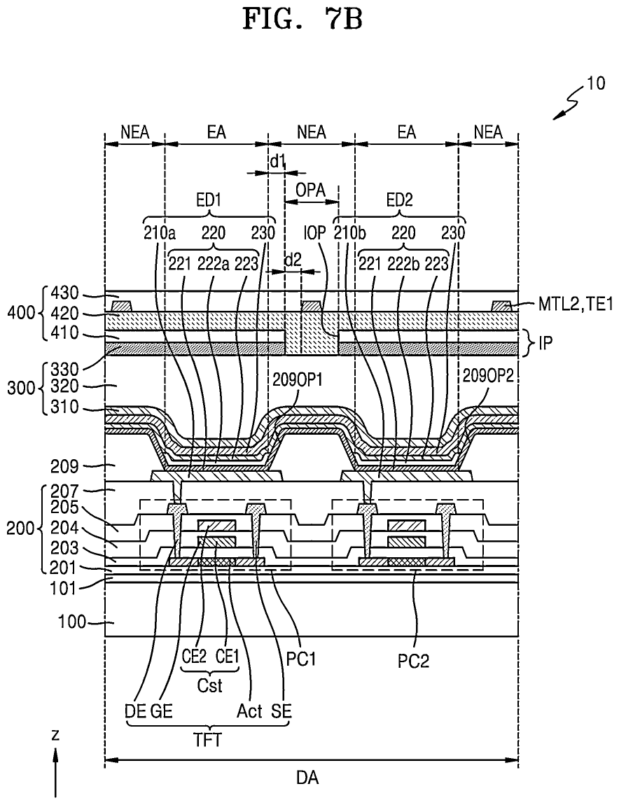

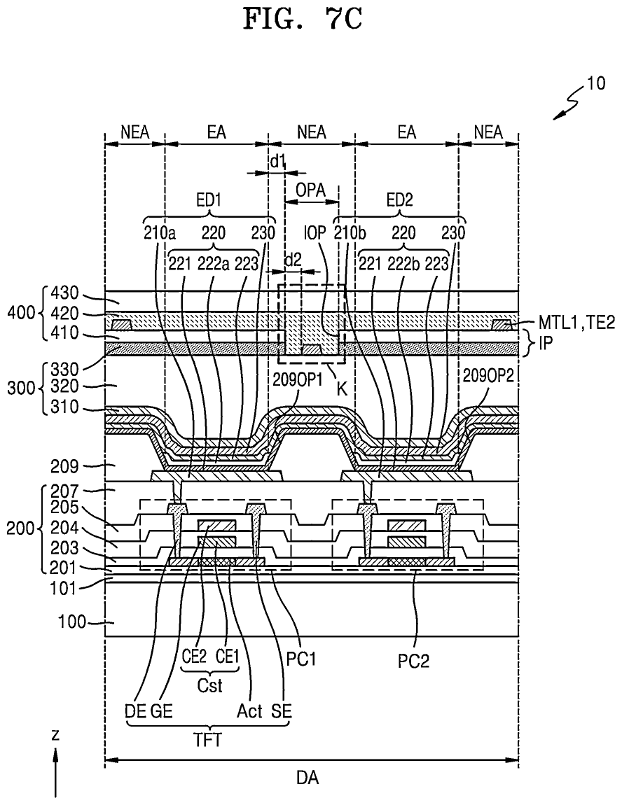

Each of the first touch electrode TE1 and the second touch electrode TE2 may be a driving electrode, a sensing electrode, or a connecting electrode forming a touch sensor. For example, the first touch electrode TE1 of FIG. 6B may correspond to the driving electrode TE of FIG. 6A, and the second touch electrode TE2 of FIG. 7C may correspond to the second connecting electrode CTE2 (see FIG. 5A), but the disclosure is not limited thereto. Touch electrodes included in the first touch conductive layer MTL1 and the second touch conductive layer MTL2 may be variously designed.

As shown in FIG. 6C, the second touch electrode TE2 included in the first touch conductive layer MTL1 may be arranged in the first opening IOP. Accordingly, at least a portion of the second touch electrode TE2 may be in direct contact with the organic encapsulation layer 320.

Each of the first touch electrode TE1 and the second touch electrode TE2 may have a mesh structure such that light emitted from the light-emitting diodes is transmitted. For example, the first touch electrode TE1 and the second touch electrode TE2 may define the electrode holes TEH overlapping the emission area EA of the first light-emitting diode ED1 and the emission area EA of the second light-emitting diode ED2 in a plan view, respectively. Mesh lines of each of the first touch electrode TE1 and the second touch electrode TE2 may overlap the non-emission area NEA in a plan view.

In a plan view, the inorganic pattern IP may be arranged inside the corresponding electrode hole TEH. For example, a boundary of the inorganic pattern IP may be spaced apart from a boundary of the mesh line defining the electrode hole TEH by a second distance d2. The second distance d2 may be about 2.5 um.

FIGS. 6B and 6C schematically illustrate an embodiment that the inorganic pattern IP includes a first inorganic layer (e.g., the second inorganic encapsulation layer 330) and a second inorganic layer (e.g., the first touch insulating layer 410), but the disclosure is not limited thereto. According to an embodiment, the inorganic pattern IP may be a single layer including only the second inorganic encapsulation layer 330, and the first touch insulating layer 410 may be omitted. According to another embodiment, the first touch insulating layer 410 may be disposed on the inorganic pattern IP, and arranged throughout the display area DA to cover the inorganic patterns IP and the first opening IOP between the inorganic patterns IP. In case that the first touch insulating layer 410 is not patterned, the second touch electrode TE2 may be disposed on a top surface of the first touch insulating layer 410 covering a bottom surface of the first opening IOP.

The second touch insulating layer 420 may be disposed on the first touch conductive layer MTL1. The second touch insulating layer 420 may provide a flat base surface by filling the first opening IOP. The second touch insulating layer 420 may include an organic material. For example, the second touch insulating layer 420 may include at least one of an acryl-based resin, a metacryl-based resin, polyisoprene, a vinyl-based resin, an epoxy-based resin, a urethane-based resin, a cellulose-based resin, and a perylene-based resin.

The third touch insulating layer 430 may be disposed on the second touch conductive layer MTL2. The third touch insulating layer 430 may have a single layer or multilayer structure. The third touch insulating layer 430 may include an organic material, an inorganic material, or a complex material. According to an embodiment, the third touch insulating layer 430 may be omitted.

FIG. 7A is a plan view of a portion of the display panel 10, according to an embodiment, and FIGS. 7B and 7C are schematic cross-sectional views of the display panel 10 of FIG. 7A. FIG. 7B is a schematic cross-sectional view of the display panel 10 taken along line J-J′ of FIG. 7A.

FIGS. 7A to 7C are similar to FIGS. 6A to 6C, but are different therefrom in that one inorganic pattern IP overlap the emission areas EA of the light-emitting diodes in a plan view. Hereinafter, differences will be described.

Referring to FIG. 7A, the display panel 10 may include the inorganic patterns IP that are spaced apart from each other. The inorganic patterns IP may each cover the emission areas EA of two or more light-emitting diodes. In this regard, FIG. 7A schematically illustrates an embodiment that one inorganic pattern IP overlaps the emission areas EA of four light-emitting diodes in a plan view.

The inorganic patterns IP may be spaced apart from each other and define the first opening IOP located between the inorganic patterns IP. The first opening IOP may overlap a portion of the pixel-defining layer 209 and not overlap the pixel opening 2090P in a plan view.

The inorganic patterns IP may each overlap two or more electrode holes the in a plan view. Accordingly, the inorganic pattern IP may overlap a portion of the driving electrode TE located between the corresponding electrode holes the in a plan view. A portion of the driving electrode TE may be disposed on the inorganic pattern IP, and the remaining portion of the driving electrode TE may be arranged inside the first opening IOP.

Referring to FIGS. 7B and 7C, the inorganic pattern IP may be disposed on the organic encapsulation layer 320. According to an embodiment, the inorganic pattern IP may be provided as a double layer of the second inorganic encapsulation layer 330 and the first touch insulating layer 410. According to another embodiment, the inorganic pattern IP may be provided as a single layer of the second inorganic encapsulation layer 330.

The first opening IOP penetrating the second inorganic encapsulation layer 330 and the first touch insulating layer 410 may be formed in the non-emission area NEA between the emission area EA of the first light-emitting diode ED1 and the emission area EA of the second light-emitting diode ED2. The first opening IOP may not be formed in the non-emission area NEA located in a direction opposite to the second light-emitting diode ED2, based on the first light-emitting diode ED1. The first opening IOP may not be formed in the non-emission area NEA located in a direction opposite to the first light-emitting diode ED1, based on the second light-emitting diode ED2.

The first touch conductive layer MTL1 may include the second touch electrode TE2, and the second touch conductive layer MTL2 may include the first touch electrode TE1. The second touch electrode TE2 of FIG. 7B may correspond to the driving electrode TE of FIG. 7A, but the disclosure is not limited thereto.

A portion of the second touch electrode TE2 arranged in the first opening area OPA may be arranged inside the first opening IOP. A portion of the second touch electrode TE2 may be in direct contact with the organic encapsulation layer 320 in the first opening IOP. A remaining portion of the second touch electrode TE2 may be disposed on the inorganic pattern IP.

The second touch insulating layer 420 may be disposed on the first touch conductive layer MTL1. The second touch insulating layer 420 may provide a flat base surface by filling the first opening IOP. The first touch electrode TE1 may be disposed on the second touch insulating layer 420.

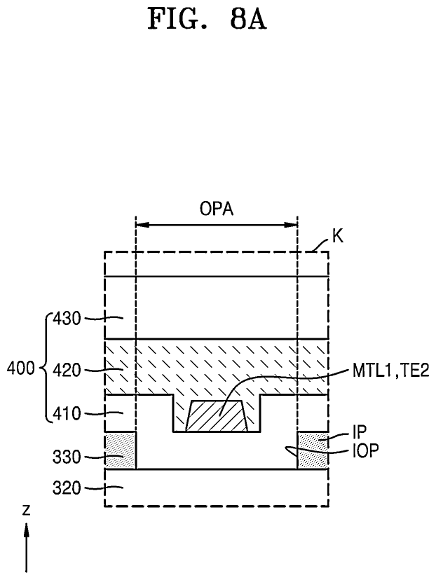

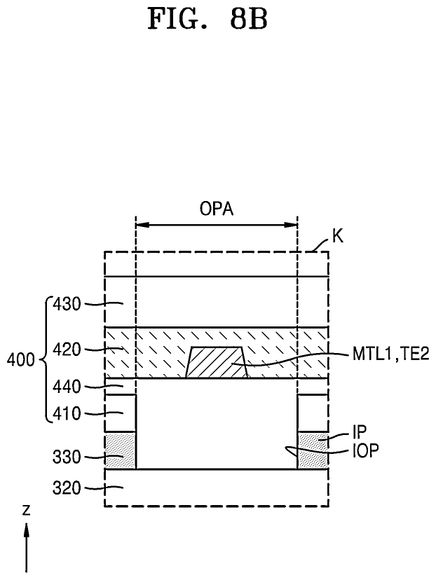

FIGS. 8A and 8B are each a schematic cross-sectional view of a portion of the display panel 10, according to an embodiment. FIGS. 8A and 8B are modified embodiments of the display panel 10 of FIG. 7B, and schematically illustrate a region corresponding to region K of FIG. 7C.

Referring to FIG. 8A, the inorganic pattern IP may be disposed on the organic encapsulation layer 320, and may be provided as a single layer of the second inorganic encapsulation layer 330. The inorganic patterns IP may be spaced apart from each other with the first opening area OPA between the inorganic patterns IP, and the neighboring inorganic patterns IP may define the first opening IOP penetrating the second inorganic encapsulation layer 330.

The touch sensor layer 400 may be disposed on the second inorganic encapsulation layer 330. The touch sensor layer 400 may include the first touch insulating layer 410, the second touch insulating layer 420, the second touch conductive layer MTL2 (see FIG. 7B), and the third touch insulating layer 430.

The first touch insulating layer 410 may be disposed on the inorganic patterns IP. The first touch insulating layer 410 may be integrally provided to cover an entire surface of the substrate 100 (see FIG. 7C). The first touch insulating layer 410 may cover the first opening IOP.

The first touch conductive layer MTL1 may include the second touch electrode TE2. The second touch electrode TE2 may have a mesh structure for defining the electrode holes TEH (see FIG. 7A). At least a portion of the second touch electrode TE2 may be arranged in the first opening area OPA. In other words, at least a portion of the second touch electrode TE2 may overlap the first opening IOP in a plan view and may be disposed on the first touch insulating layer 410 inside the first opening IOP.

The second touch insulating layer 420 may be disposed on the first touch insulating layer 410. The second touch insulating layer 420 may provide a flat base surface to the second touch conductive layer MTL2 by filling a stepped difference caused by the first opening IOP. The third touch insulating layer 430 may be disposed on the second touch insulating layer 420. According to an embodiment, the third touch insulating layer 430 may be omitted.

Referring to FIG. 8B, the inorganic pattern IP may be disposed on the organic encapsulation layer 320, and may be provided as a double layer of the second inorganic encapsulation layer 330 and the first touch insulating layer 410. The inorganic patterns IP may be spaced apart from each other with the first opening area OPA between the inorganic patterns IP, and the neighboring inorganic patterns IP may define the first opening IOP penetrating the second inorganic encapsulation layer 330 and the first touch insulating layer 410.

An organic layer 440 may be arranged between the first touch insulating layer 410 and the second touch insulating layer 420. The organic layer 440 may provide a flat base surface to the first touch conductive layer MTL1 by filling a stepped difference caused by the first opening IOP. The organic layer 440 may include an organic material. For example, the organic layer 440 may include at least one of an acryl-based resin, a metacryl-based resin, polyisoprene, a vinyl-based resin, an epoxy-based resin, a urethane-based resin, a cellulose-based resin, and a perylene-based resin.

The first touch conductive layer MTL1 may be disposed on the organic layer 440. The first touch conductive layer MTL1 may include the second touch electrode TE2. The second touch electrode TE2 may have a mesh structure for defining the electrode holes TEH (see FIG. 7A). At least a portion of the second touch electrode TE2 may be arranged in the first opening area OPA. In other words, at least a portion of the second touch electrode TE2 may overlap the first opening IOP in a plan view. The second touch electrode TE2 may be disposed on the organic layer 440.

The second touch insulating layer 420 may be disposed on the first touch insulating layer 410. The third touch insulating layer 430 may be disposed on the second touch insulating layer 420. According to an embodiment, the third touch insulating layer 430 may be omitted.

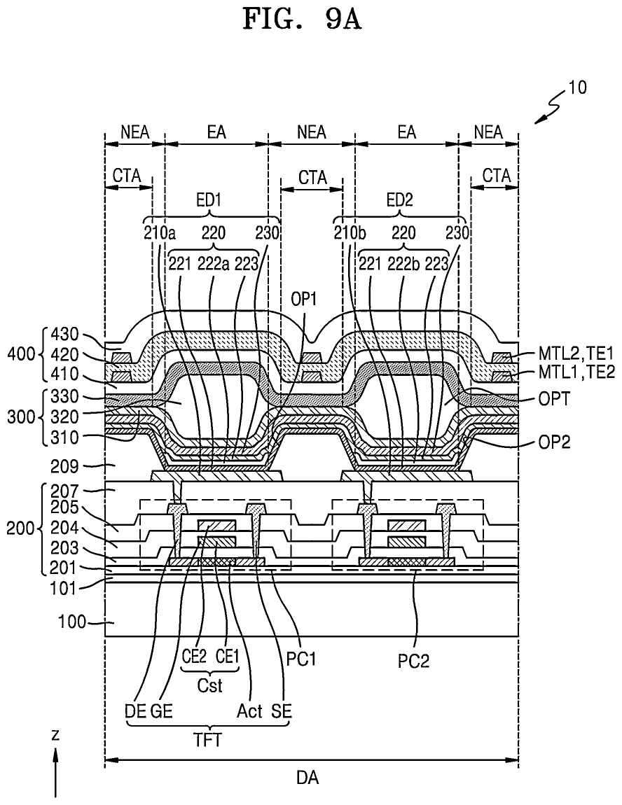

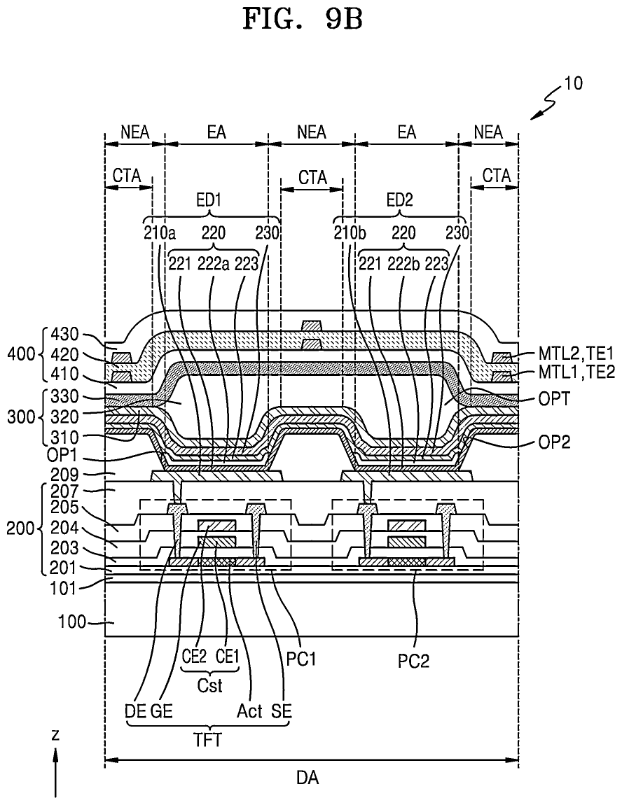

FIGS. 9A and 9B are each a schematic cross-sectional view of a portion of the display panel 10, according to an embodiment. FIGS. 9A and 9B are similar to FIG. 6B, but are different therefrom in that organic patterns OPT are formed instead of inorganic patterns.

Referring to FIG. 9A, the pixel circuit layer 200, the first and second light-emitting diodes ED1 and ED2, the encapsulation layer 300, and the touch sensor layer 400 may be sequentially stacked on the display area DA of the substrate 100. The first and second pixel circuits PC1 and PC2, which are electrically connected to the first and second light-emitting diodes ED1 and ED2, may be arranged in the pixel circuit layer 200.

The encapsulation layer 300 may be disposed on the first light-emitting diode ED1 and the second light-emitting diode ED2. According to an embodiment, the encapsulation layer 300 may include at least one inorganic encapsulation layer and at least one organic encapsulation layer. For example, the encapsulation layer 300 may include first and second inorganic encapsulation layers 310 and 330, and the organic encapsulation layer 320 between the first and second inorganic encapsulation layers 310 and 330.

The first inorganic encapsulation layer 310 may be disposed on the opposing electrode 230. The first inorganic encapsulation layer 310 may be a single layer or multilayer including an inorganic insulating material, such as silicon oxide, silicon nitride, and/or silicon oxynitride.

The organic encapsulation layer 320 may be disposed on the first inorganic encapsulation layer 310, and the organic patterns OPT covering each of the emission area EA of the first light-emitting diode ED1 and the emission area EA of the second light-emitting diode ED2 may be formed. The organic patterns OPT may include polyethylene terephthalate, polyethylene naphthalate, polycarbonate, polyimide, polyethylene sulfonate, polyoxymethylene, polyarylate, HMDSO, acryl-based resin, or a combination thereof.

The width (or the area) of the organic pattern OPT may be greater than the width (or the area) of the corresponding emission area EA. For example, the organic pattern OPT corresponding to the emission area EA of the first light-emitting diode ED1 may embed a first pixel opening OP1 and partially overlap the pixel-defining layer 209 in a plan view. Similarly, the organic pattern OPT corresponding to the emission area EA of the second light-emitting diode ED2 may embed a second pixel opening OP2 and partially overlap the pixel-defining layer 209 in a plan view.

The second inorganic encapsulation layer 330 may be disposed on the organic encapsulation layer 320. The second inorganic encapsulation layer 330 may be consecutively formed to cover an entire surface of the display area DA. The second inorganic encapsulation layer 330 may be a single layer or multilayer including an inorganic insulating material, such as silicon oxide, silicon nitride, and/or silicon oxynitride.

The touch sensor layer 400 may be disposed on the encapsulation layer 300. The touch sensor layer 400 may include the first touch insulating layer 410, the first touch conductive layer MTL1, the second touch insulating layer 420, the second touch conductive layer MTL2, and the third touch insulating layer 430.

The first touch insulating layer 410 may be disposed on (e.g., disposed directly on) the encapsulation layer 300. The first touch insulating layer 410 may be a single layer or multilayer including an inorganic insulating material, such as silicon oxide, silicon nitride, and/or silicon oxynitride. The first touch insulating layer 410 may be consecutively formed to cover an entire surface of the display area DA.

A contact area CTA may be defined between the organic patterns OPT that are spaced apart from each other. The contact area CTA may be an area where the second inorganic encapsulation layer 330 and the first touch insulating layer 410 are in direct contact with each other to form inorganic contact. In case that the second inorganic encapsulation layer 330 and the first touch insulating layer 410 are in direct contact with each other and form the inorganic contact, a path through which impurities, such as moisture, are penetrated to a neighboring pixel may not be expanded even in case that a portion of an inorganic layer is cracked or the like.

The first touch conductive layer MTL1 may include the second touch electrode TE2. The second touch electrode TE2 may not overlap the emission area EA of the first light-emitting diode ED1 and the emission area EA of the second light-emitting diode ED2 in a plan view. The second touch electrode TE2 may not overlap the organic patterns OPT in a plan view and may be arranged in a region between the organic patterns OPT.

The second touch insulating layer 420 may be disposed on the first touch conductive layer MTL1. The second touch insulating layer 420 may include an organic material. The second touch conductive layer MTL2 may be disposed on the second touch insulating layer 420. The second touch conductive layer MTL2 may include the first touch electrode TE1. The first touch electrode TE1 may not overlap the emission area EA of the first light-emitting diode ED1 and the emission area EA of the second light-emitting diode ED2 in a plan view. The first touch electrode TE1 may not overlap the organic patterns OPT in a plan view and may be arranged in a region between the organic patterns OPT. Each of the first touch conductive layer MTL1 and the second touch conductive layer MTL2 may have a single layer structure or a stacked multilayer structure.

The third touch insulating layer 430 may be disposed on the second touch conductive layer MTL2. The third touch insulating layer 430 may have a single layer or multilayer structure. The third touch insulating layer 430 may include an organic material, an inorganic material, or a complex material. According to an embodiment, the third touch insulating layer 430 may be omitted.

Referring to FIG. 9B, the organic encapsulation layer 320 may be disposed on the first inorganic encapsulation layer 310, and may form the organic pattern OPT simultaneously covering the emission areas EA of two or more light-emitting diodes. For example, one organic pattern OPT may overlap the emission area EA of the first light-emitting diode ED1 and the emission area EA of the second light-emitting diode ED2 in a plan view.

The touch sensor layer 400 may be disposed on the encapsulation layer 300. The touch sensor layer 400 may include the first touch insulating layer 410, the first touch conductive layer MTL1, the second touch insulating layer 420, the second touch conductive layer MTL2, and the third touch insulating layer 430.

The first touch insulating layer 410 may be disposed on (e.g., disposed directly on) the encapsulation layer 300. The first touch insulating layer 410 may be a single layer or multilayer including an inorganic insulating material, such as silicon oxide, silicon nitride, and/or silicon oxynitride. The first touch insulating layer 410 may be consecutively formed to cover an entire surface of the display area DA.

The contact area CTA may be defined between the organic patterns OPT that are spaced apart from each other. The contact area CTA may be an area where the second inorganic encapsulation layer 330 and the first touch insulating layer 410 are in direct contact with each other to form the inorganic contact. In case that the second inorganic encapsulation layer 330 and the first touch insulating layer 410 are in direct contact with each other and form the inorganic contact, a path through which impurities, such as moisture, are penetrated to a neighboring pixel may not be expanded even in case that a portion of an inorganic layer is cracked or the like.

In case that a portion (e.g., an edge region) of the display panel 10 is bent in the rear direction of the substrate 100 to have a specific curvature, the light-emitting diodes may be damaged as stress is concentrated on some region. According to an embodiment, the organic patterns OPT that are spaced apart from each other may be formed by patterning the organic encapsulation layer 320, and thus, the elongation of the top surface of the display panel 10 may be increased, thereby reducing or preventing the stress from concentrating on a region. Accordingly, reliability of the display panel 10 may be increased.

According to an embodiment, the organic patterns OPT may be formed only in a portion (e.g., the edge region) of the display panel 10. In other words, the organic encapsulation layer 320 may be not patterned but may be integrally formed in a flat region (e.g., the center area CA, see FIG. 1) of the display panel 10.

According to another embodiment, the organic patterns OPT may be formed throughout the display area DA (see FIG. 1) of the display panel 10.

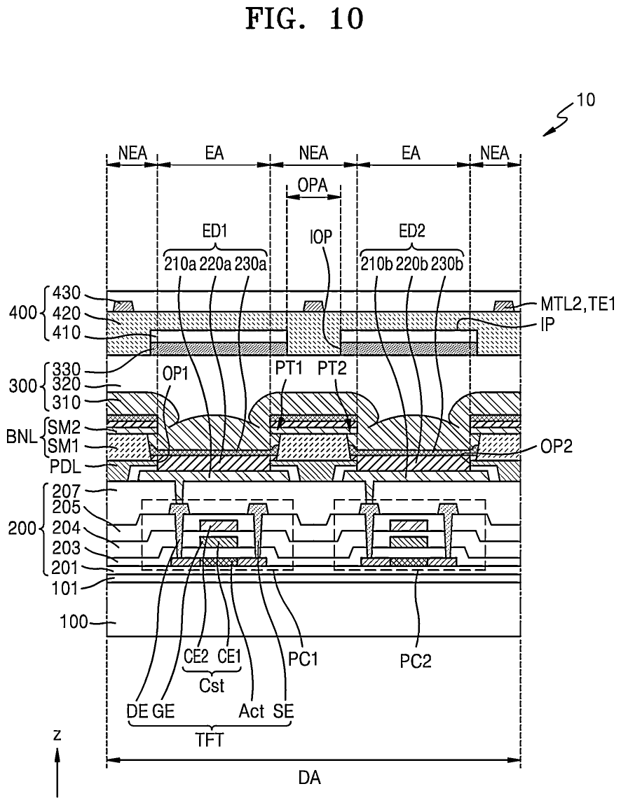

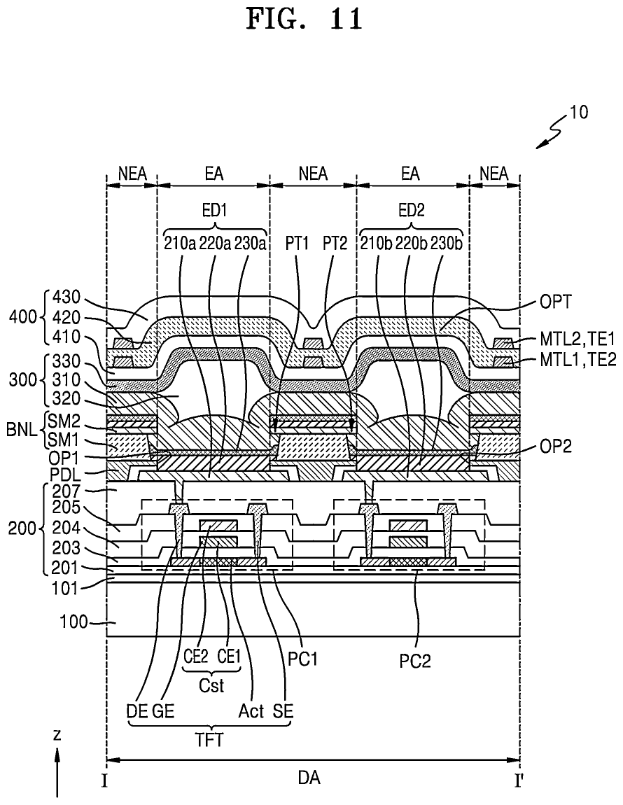

FIGS. 10 and 11 are schematic cross-sectional views of a portion of the display panel 10, according to an embodiment. FIG. 10 is similar to FIG. 6B and FIG. 11 is similar to FIG. 9A, but FIGS. 10 and 11 are different from FIGS. 6B and 9A in that a pixel-defining layer PDL defining the emission areas EA of the light-emitting diodes may include an inorganic material, and a metal bank layer BNL may be further disposed on the pixel-defining layer PDL. Hereinafter, differences will be described.

Referring to FIG. 10, the pixel circuit layer 200, the first and second light-emitting diodes ED1 and ED2, the encapsulation layer 300, and the touch sensor layer 400 may be sequentially stacked on the display area DA of the substrate 100. The first and second pixel circuits PC1 and PC2, which are electrically connected to the first and second light-emitting diodes ED1 and ED2, may be arranged in the pixel circuit layer 200.

The first light-emitting diode ED1 and the second light-emitting diode ED2 may be disposed on the planarization insulating layer 207 of the pixel circuit layer 200. The first light-emitting diode ED1 may be electrically connected to the first pixel circuit PC1, and the second light-emitting diode ED2 may be electrically connected to the second pixel circuit PC2. The first light-emitting diode ED1 may include the first pixel electrode 210a, a first intermediate layer 220a, and a first opposing electrode 230a, and the second light-emitting diode ED2 may include the second pixel electrode 210b, a second intermediate layer 220b, and a second opposing electrode 230b. The first light-emitting diode ED1 and the second light-emitting diode ED2 may have a substantially same or similar structure. Hereinafter, the first light-emitting diode ED1 will be described.

The first pixel electrode 210a and the second pixel electrode 210b may be disposed on the planarization insulating layer 207. The first pixel electrode 210a may be electrically connected to the first pixel circuit PC1, and the second pixel electrode 210b may be electrically connected to the second pixel circuit PC2.

The first intermediate layer 220a and the second intermediate layer 220b may each include an emission layer emitting light of a color. The emission layer may include a high-molecular weight or low-molecular weight organic material. The first intermediate layer 220a and the second intermediate layer 220b may each include a first functional layer disposed below the emission layer and a second functional layer disposed on the emission layer. The first functional layer may include a hole transport layer and/or a hole injection layer. The second functional layer may include an electron transport layer and/or an electron injection layer.

The first opposing electrode 230a and the second opposing electrode 230b may include a conductive material with a low work function. For example, the first opposing electrode 230a and the second opposing electrode 230b may include a (semi-)transparent layer including Ag, Mg, Al, Pt, Pd, Au, Ni, Nd, Ir, Cr, Li, Ca, or an alloy thereof. The first opposing electrode 230a and the second opposing electrode 230b may further include a layer including ITO, IZO, ZnO, or In₂O₃, on the (semi-)transparent layer including the above material.

The pixel-defining layer PDL may be disposed on the planarization insulating layer 207 and cover an edge of each of the first pixel electrode 210a and the second pixel electrode 210b. The pixel-defining layer PDL may include the first pixel opening OP1 exposing a portion of the first pixel electrode 210a and the second pixel opening OP2 exposing a portion of the second pixel electrode 210b. The first pixel opening OP1 may define the emission area EA of the first light-emitting diode ED1, and the second pixel opening OP2 may define the emission area EA of the second light-emitting diode ED2.

The pixel-defining layer PDL may include an inorganic material, such as silicon oxide, silicon nitride, and/or silicon oxynitride, and have a single layer or multilayer structure. The pixel-defining layer PDL may increase a distance between the edge of the first pixel electrode 210a and the first opposing electrode 230a, and a distance between the edge of the second pixel electrode 210b and the second opposing electrode 230b, thereby preventing arc therebetween.

A remaining sacrificial layer may be arranged between the pixel-defining layer PDL, and the first pixel electrode 210a and the second pixel electrode 210b. The remaining sacrificial layer may be a portion of a sacrificial layer for preventing surfaces of the first pixel electrode 210a and the second pixel electrode 210b from being damaged during a process.

The metal bank layer BNL may be disposed on the pixel-defining layer PDL. The metal bank layer BNL may include a first sub-metal layer SM1 and a second sub-metal layer SM2. The first sub-metal layer SM1 and the second sub-metal layer SM2 may include different metals. According to embodiments, the first sub-metal layer SM1 may include Al or Mo, and the second sub-metal layer SM2 may include Ti or Ta.

The first sub-metal layer SM1 may define first bank openings respectively overlapping the first pixel opening OP1 and the second pixel opening OP2 in a plan view, and the second sub-metal layer SM2 may define second bank openings respectively overlapping the first pixel opening OP1 and the second pixel opening OP2 in a plan view. The width (or the area) of the first bank opening defined in the first sub-metal layer SM1 may be greater than the width (or the area) defined in the second sub-metal layer SM2. In other words, an undercut structure in which the second sub-metal layer SM2 protrudes as a portion of the first sub-metal layer SM1 located below the second sub-metal layer SM2 is removed may be formed. Accordingly, the second sub-metal layer SM2 may include a first tip PT1 protruding to a center of the first pixel opening OP1 from a side surface of the first sub-metal layer SM1, and a second tip PT2 protruding to a center of the second pixel opening OP2 from the side surface of the first sub-metal layer SM1.

Dummy stacks may be disposed on a top surface of the second sub-metal layer SM2. A first dummy stack located in a region adjacent to the first light-emitting diode ED1 may include dummy layers. For example, the dummy layers of the first dummy stack, the first intermediate layer 220a, and the first opposing electrode 230a may include a same material. A second dummy stack located in a region adjacent to the second light-emitting diode ED2 may include dummy layers. For example, the dummy layers of the second dummy stack, the second intermediate layer 220b, and the second opposing electrode 230b may include a same material.

The first opposing electrode 230a may be in direct contact with a side surface of the first sub-metal layer SM1 in the first pixel opening OP1. The first opposing electrode 230a may be in direct contact with a side surface of the first sub-metal layer SM1 in the second pixel opening OP2. The metal bank layer BNL may be electrically connected to a voltage line configured to transmit a common power voltage, and the first opposing electrode 230a and the second opposing electrode 230b may receive a second power voltage.

The encapsulation layer 300 may be disposed on the first light-emitting diode ED1 and the second light-emitting diode ED2. The encapsulation layer 300 may include at least one inorganic encapsulation layer and at least one organic encapsulation layer. For example, the encapsulation layer 300 may include the first and second inorganic encapsulation layers 310 and 330, and the organic encapsulation layer 320 therebetween.

The first inorganic encapsulation layer 310 may be disposed on the first opposing electrode 230a and the second opposing electrode 230b. The first inorganic encapsulation layer 310 may be a single layer or multilayer including an inorganic insulating material, such as silicon oxide, silicon nitride, and/or silicon oxynitride. The first inorganic encapsulation layer 310 has a relatively high step coverage, and thus may be in direct contact with the side surface of the first sub-metal layer SM1 and a bottom surface of the first tip PT1, where the first intermediate layer 220a and the first opposing electrode 230a are not formed, by the first tip PT1. Similarly, the first inorganic encapsulation layer 310 may be in direct contact with the side surface of the first sub-metal layer SM1 and a bottom surface of the second tip PT2, where the second intermediate layer 220b and the second opposing electrode 230b are not formed. Accordingly, the first inorganic encapsulation layer 310 may seal each of the first light-emitting diode ED1 and the second light-emitting diode ED2.

The organic encapsulation layer 320 may be disposed on the first inorganic encapsulation layer 310. The organic encapsulation layer 320 may include polyethylene terephthalate, polyethylene naphthalate, polycarbonate, polyimide, polyethylene sulfonate, polyoxymethylene, polyarylate, HMDSO, an acryl-based resin, or a combination thereof.

The second inorganic encapsulation layer 330 may be disposed on the organic encapsulation layer 320. The second inorganic encapsulation layer 330 may be a single layer or multilayer including an inorganic insulating material, such as silicon oxide, silicon nitride, and/or silicon oxynitride. The second inorganic encapsulation layer 330 may be formed through chemical vapor deposition.

The second inorganic encapsulation layer 330 may form the inorganic patterns IP covering each of the emission area EA of the first light-emitting diode ED1 and the emission area EA of the second light-emitting diode ED2. For example, FIG. 10 schematically illustrates the inorganic patterns IP formed in a double layer of the second inorganic encapsulation layer 330 (first inorganic layer) and the first touch insulating layer 410 (second inorganic layer) described above. However, the disclosure is not limited thereto, and according to another embodiment, the inorganic patterns IP may be formed as a single layer of the second inorganic encapsulation layer 330.

The touch sensor layer 400 may have a multilayer structure. The touch sensor layer 400 may include a sensing electrode, a sensing signal line connected to the sensing electrode, a driving electrode, a driving signal line connected to the driving electrode, and at least one insulating layer. The touch sensor included in the touch sensor layer 400 may sense an external input through, for example, capacitance.

The touch sensor layer 400 may include the first touch insulating layer 410, the first touch conductive layer MTL1, the second touch insulating layer 420, the second touch conductive layer MTL2, and the third touch insulating layer 430.

The first touch insulating layer 410 may be disposed on (e.g., disposed directly on) the encapsulation layer 300. The first touch insulating layer 410 may be a single layer or multilayer including an inorganic insulating material, such as silicon oxide, silicon nitride, and/or silicon oxynitride.

The first touch insulating layer 410 may form the inorganic patterns IP covering each of the emission area EA of the first light-emitting diode ED1 and the emission area EA of the second light-emitting diode ED2. The width (or the area) of the inorganic pattern IP may be greater than the width (or the area) of the corresponding emission area EA. According to another embodiment, the inorganic pattern IP may cover the emission areas EA of two or more light-emitting diodes.

The first opening IOP may be defined between the neighboring inorganic patterns IP. The first opening IOP may be an opening penetrating the first touch insulating layer 410 and the second inorganic encapsulation layer 330. The first opening area OPA where the first opening IOP is arranged may overlap the non-emission area NEA in a plan view. In other words, the first opening IOP may not overlap the first pixel opening 2090P1 and the second pixel opening 2090P2 in a plan view.

In case that a portion (e.g., the edge region) of the display panel 10 is bent in the rear direction of the substrate 100 to have a specific curvature, the light-emitting diodes may be damaged as stress is concentrated on some region. According to an embodiment, an inorganic layer on the organic encapsulation layer 320, for example, the second inorganic encapsulation layer 330 and the first touch insulating layer 410, may be patterned to form the inorganic patterns IP spaced apart from each other, and thus, elongation of the top surface of the display panel 10 may be increased, thereby reducing or preventing the stress from being concentrated on some region. Accordingly, reliability of the display panel 10 may be increased.

According to an embodiment, the inorganic patterns IP may be formed only in a portion (e.g., the edge region) of the display panel 10. In other words, the second inorganic encapsulation layer 330 and/or the first touch insulating layer 410 may be not patterned but may be integrally formed in a flat region (e.g., the center area CA, see FIG. 1) of the display panel 10.

According to another embodiment, the inorganic patterns IP may be formed throughout the display area DA (see FIG. 1) of the display panel 10.

The first touch conductive layer MTL1 may be disposed on the first touch insulating layer 410. The first touch conductive layer MTL1 may include multiple patterns. The second touch electrode TE2 included in the first touch conductive layer MTL1 may be arranged in the first opening IOP. Accordingly, at least a portion of the second touch electrode TE2 may be in direct contact with the organic encapsulation layer 320.

FIG. 10 schematically illustrates an embodiment that the inorganic pattern IP includes a first inorganic layer (e.g., the second inorganic encapsulation layer 330) and a second inorganic layer (e.g., the first touch insulating layer 410), but the disclosure is not limited thereto. According to an embodiment, the inorganic pattern IP may be a single layer including only the second inorganic encapsulation layer 330, and the first touch insulating layer 410 may be omitted. According to another embodiment, the first touch insulating layer 410 may be disposed on the inorganic pattern IP, and cover the inorganic patterns IP and the first opening IOP between the inorganic patterns IP. In case that the first touch insulating layer 410 is not patterned, the second touch electrode TE2 may be disposed on the first touch insulating layer 410 covering the bottom surface of the first opening IOP, as described with reference to FIG. 8A. According to another embodiment, as described with reference to FIG. 8B, the touch sensor layer 400 may further include the organic layer 440 filling the first opening IOP between the first touch insulating layer 410 and the second touch insulating layer 420.

The second touch insulating layer 420 may be disposed on the first touch conductive layer MTL1. The second touch insulating layer 420 may provide a flat base surface by filling the first opening IOP. The second touch insulating layer 420 may include an organic material. The second touch conductive layer MTL2 may be disposed on the second touch insulating layer 420. The second touch conductive layer MTL2 may include the first touch electrode TE1.

The third touch insulating layer 430 may be disposed on the second touch conductive layer MTL2. The third touch insulating layer 430 may have a single layer or multilayer structure. The third touch insulating layer 430 may include an organic material, an inorganic material, or a complex material. According to an embodiment, the third touch insulating layer 430 may be omitted.

Referring to FIG. 11, the encapsulation layer 300 may be disposed on the first light-emitting diode ED1 and the second light-emitting diode ED2. According to an embodiment, the encapsulation layer 300 may include at least one inorganic encapsulation layer and at least one organic encapsulation layer. For example, the encapsulation layer 300 may include the first and second inorganic encapsulation layers 310 and 330, and the organic encapsulation layer 320 between the first and second inorganic encapsulation layers 310 and 330.

The first inorganic encapsulation layer 310 may be disposed on the first opposing electrode 230a and the second opposing electrode 230b. The first inorganic encapsulation layer 310 may be a single layer or multilayer including an inorganic insulating material, such as silicon oxide, silicon nitride, and/or silicon oxynitride.

The organic encapsulation layer 320 may be disposed on the first inorganic encapsulation layer 310, and the organic patterns OPT covering each of the emission area EA of the first light-emitting diode ED1 and the emission area EA of the second light-emitting diode ED2 may be formed. FIG. 11 schematically illustrates the organic pattern OPT overlapping one emission area EA in a plan view, but the disclosure is not limited thereto. According to another embodiment, one organic pattern OPT may overlap the emission areas EA of two or more light-emitting diodes in a plan view.

The width (or the area) of the organic pattern OPT may be greater than the width (or the area) of the corresponding emission area EA. For example, the organic pattern OPT corresponding to the emission area EA of the first light-emitting diode ED1 may embed the first pixel opening OP1 and partially overlap the pixel-defining layer PDL and the metal bank layer BNL in a plan view. Similarly, the organic pattern OPT corresponding to the emission area EA of the second light-emitting diode ED2 may embed the second pixel opening OP2 and partially overlap the pixel-defining layer PDL and the metal bank layer BNL in a plan view.

The second inorganic encapsulation layer 330 may be disposed on the organic encapsulation layer 320. The second inorganic encapsulation layer 330 may be consecutively formed to cover an entire surface of the display area DA. The second inorganic encapsulation layer 330 may be a single layer or multilayer including an inorganic insulating material, such as silicon oxide, silicon nitride, and/or silicon oxynitride.

The touch sensor layer 400 may be disposed on the encapsulation layer 300. The touch sensor layer 400 may include the first touch insulating layer 410, the first touch conductive layer MTL1, the second touch insulating layer 420, the second touch conductive layer MTL2, and the third touch insulating layer 430.

The first touch insulating layer 410 may be disposed on (e.g., disposed directly on) the encapsulation layer 300. The first touch insulating layer 410 may be a single layer or multilayer including an inorganic insulating material, such as silicon oxide, silicon nitride, and/or silicon oxynitride. The first touch insulating layer 410 may be consecutively formed to cover an entire surface of the display area DA.

Between the organic patterns OPT that are spaced apart from each other, the second inorganic encapsulation layer 330 and the first touch insulating layer 410 may form inorganic contact by being in direct contact with each other. Accordingly, a path through which impurities, such as moisture, are penetrated to a neighboring pixel may not be expanded even in case that a portion of an inorganic layer is cracked or the like.

The first touch conductive layer MTL1 may include the second touch electrode TE2. The second touch electrode TE2 may not overlap the emission area EA of the first light-emitting diode ED1 and the emission area EA of the second light-emitting diode ED2 in a plan view. The second touch electrode TE2 may not overlap the organic patterns OPT in a plan view and may be arranged in a region between the organic patterns OPT.

The second touch insulating layer 420 may be disposed on the first touch conductive layer MTL1. The second touch insulating layer 420 may include an organic material. The second touch conductive layer MTL2 may be disposed on the second touch insulating layer 420. The second touch conductive layer MTL2 may include the first touch electrode TE1. Each of the first touch conductive layer MTL1 and the second touch conductive layer MTL2 may have a single layer structure or a stacked multilayer structure.

The third touch insulating layer 430 may be disposed on the second touch conductive layer MTL2. The third touch insulating layer 430 may have a single layer or multilayer structure. The third touch insulating layer 430 may include an organic material, an inorganic material, or a complex material. According to an embodiment, the third touch insulating layer 430 may be omitted.

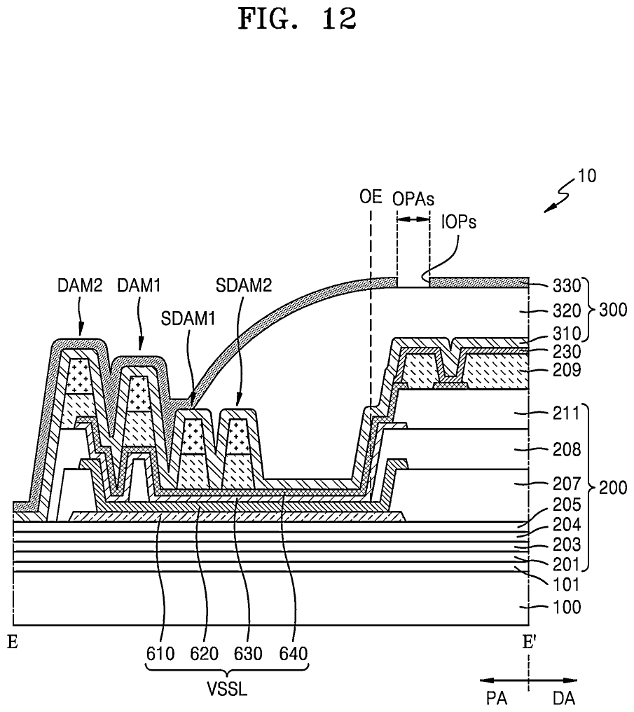

FIG. 12 is a schematic cross-sectional view of the display panel 10 taken along line E-E′ of FIG. 3.

Referring to FIG. 12, the barrier layer 101, and inorganic insulating layers and organic insulating layers configuring the pixel circuit layer 200 may be disposed on the substrate 100. The inorganic insulating layers may include the buffer layer 201, the first gate insulating layer 203, the second gate insulating layer 204, and the interlayer insulating layer 205, but the disclosure is not limited thereto, and according to an embodiment, some thereof may be omitted or another layer may be added. The organic insulating layers may include the planarization insulating layer 207, a first organic insulating layer 208, and a second organic insulating layer 211. The planarization insulating layer 207 may be a first planarization insulating layer, the first organic insulating layer 208 may be a second planarization insulating layer, and the second organic insulating layer 211 may be a third planarization insulating layer. Some of the planarization insulating layer 207, the first organic insulating layer 208, and the second organic insulating layer 211 may be omitted, or another organic insulating layer may be added. The pixel-defining layer 209 may be disposed on the second organic insulating layer 211.

The buffer layer 201, the first gate insulating layer 203, the second gate insulating layer 204, and the interlayer insulating layer 205 may be arranged on an entire surface of the substrate 100. The planarization insulating layer 207, the first organic insulating layer 208, the second organic insulating layer 211, and the pixel-defining layer 209 may extend from the display area DA and cover a portion of the peripheral area PA. Among end portions of the planarization insulating layer 207, the first organic insulating layer 208, the second organic insulating layer 211, and the pixel-defining layer 209, end portions that are farthest from the display area DA may be defined as ends OE of the organic insulating layers.

A common voltage line VSSL may be disposed on the interlayer insulating layer 205. The common voltage line VSSL may be arranged adjacent to an edge of the substrate 100, and have a loop shape having a side opened to surround at least a portion of the display area DA in a plan view.

The common voltage line VSSL may include one or more metal wires. For example, the common voltage line VSSL may include a first metal wire 610, a second metal wire 620, a third metal wire 630, and a fourth metal wire 640, which overlap each other. The first metal wire 610 and electrodes and wires arranged between the interlayer insulating layer 205 and the planarization insulating layer 207 may include a same material. The second metal wire 620 and electrodes and wires arranged between the planarization insulating layer 207 and the first organic insulating layer 208 may include a same material. The third metal wire 630 and electrodes and wires arranged between the first organic insulating layer 208 and the second organic insulating layer 211 may include a same material. The fourth metal wire 640 and pixel electrodes of light-emitting diodes may include a same material. One or more of the first metal wire 610, the second metal wire 620, the third metal wire 630, and the fourth metal wire 640 may be omitted.

An inner boundary (e.g., a direction in the display area DA) of the common voltage line VSSL may overlap the organic insulating layers in a plan view. For example, an inner boundary of the first metal wire 610 may be arranged between the interlayer insulating layer 205 and the planarization insulating layer 207, an inner boundary of the second metal wire 620 may be arranged between the planarization insulating layer 207 and the first organic insulating layer 208, an inner boundary of the third metal wire 630 may be arranged between the first organic insulating layer 208 and the second organic insulating layer 211, and an inner boundary of the fourth metal wire 640 may be arranged between the second organic insulating layer 211 and the pixel-defining layer 209.

The pixel-defining layer 209 may include openings for exposing a portion of the fourth metal wire 640. The opposing electrode 230 may be in direct contact with the fourth metal wire 640 through the openings of the pixel-defining layer 209. In other words, the opposing electrode 230 may be electrically connected to the common voltage line VSSL.

A second dam DAM2 may overlap an outer boundary (e.g., a direction in the edge of the substrate 100) of the common voltage line VSSL in a plan view. A first dam DAM1 may be spaced apart from the second dam DAM2, on the common voltage line VSSL. The first dam DAM1 and the second dam DAM2 may include multiple organic layers.

One or more sub-dams may be disposed on the common voltage line VSSL. In this regard, FIG. 12 schematically illustrates a first sub-dam SDAM1 and a second sub-dam SDAM2 being disposed on the common voltage line VSSL. The first sub-dam SDAM1 and the second sub-dam SDAM2 may include multiple organic layers.

The first dam DAM1, the second dam DAM2, the first sub-dam SDAM1, and the second sub-dam SDAM2 may be configurations for controlling the organic encapsulation layer 320 of the encapsulation layer 300. For example, the first inorganic encapsulation layer 310 and the second inorganic encapsulation layer 330 may be in direct contact a top surface of the second dam DAM2, because the organic encapsulation layer 320 may not reach the top surface of the second dam DAM2. Accordingly, a path through which impurities, such as moisture, penetrate to the display area DA through the organic encapsulation layer 320 from the outside of the substrate 100 may be blocked or reduced.

The encapsulation layer 300 may be arranged to cover the opposing electrode 230, the common voltage line VSSL, the first dam DAM1, the second dam DAM2, the first sub-dam SDAM1, and the second sub-dam SDAM2. The encapsulation layer 300 may include at least one inorganic encapsulation layer and one organic encapsulation layer. According to an embodiment, the encapsulation layer 300 may include the first inorganic encapsulation layer 310, the second inorganic encapsulation layer 330, and the organic encapsulation layer 320 between the first inorganic encapsulation layer 310 and the second inorganic encapsulation layer 330.

The first inorganic encapsulation layer 310 may cover an entire surface of the substrate 100. The organic encapsulation layer 320 may extend from the display area DA to the first dam DAM1 or the second dam DAM2. As described above, the first dam DAM1, the second dam DAM2, the first sub-dam SDAM1, and the second sub-dam SDAM2 may control a flow of the organic encapsulation layer 320.

The second inorganic encapsulation layer 330 may be disposed on the organic encapsulation layer 320. The second inorganic encapsulation layer 330 may be divided into an outer portion and an inner portion with a second opening area OPAs between the outer portion and the inner portion. The second inorganic encapsulation layer 330 may include a second opening IOPs extending in a direction parallel to the edge of the substrate 100 and overlapping the second opening area OPAs. The second opening IOPs may be arranged in the peripheral area PA and overlap the organic encapsulation layer 320 in a plan view. In other words, the second opening IOPs may be located inside (e.g., the direction in the display area DA) the first dam DAM1 and the second dam DAM2 in a plan view. The second opening IOPs may have a loop shape and surround at least a portion of the display area DA, along the edge of the substrate 100 in a plan view. According to an embodiment, the second opening IOPs may be located closer to the display area DA than to the ends OE of the organic insulating layers.

FIG. 12 schematically illustrates that one second opening IOPs is arranged in the second opening area OPAs, but the disclosure is not limited thereto. According to another embodiment, multiple second openings IOPs may be arranged in the second opening area OPAs. Each second opening IOPs may have a loop shape and surround at least a portion of the display area DA in a plan view.

The peripheral area PA of the display panel 10 may be bent to have a specific curvature in the rear direction of the substrate 100. Light-emitting diodes may be damaged as stress is concentrated on some region. According to an embodiment, the second opening IOPs may be formed in the second inorganic encapsulation layer 330 to prevent or reduce generation of a crack in a region where the stress is concentrated.

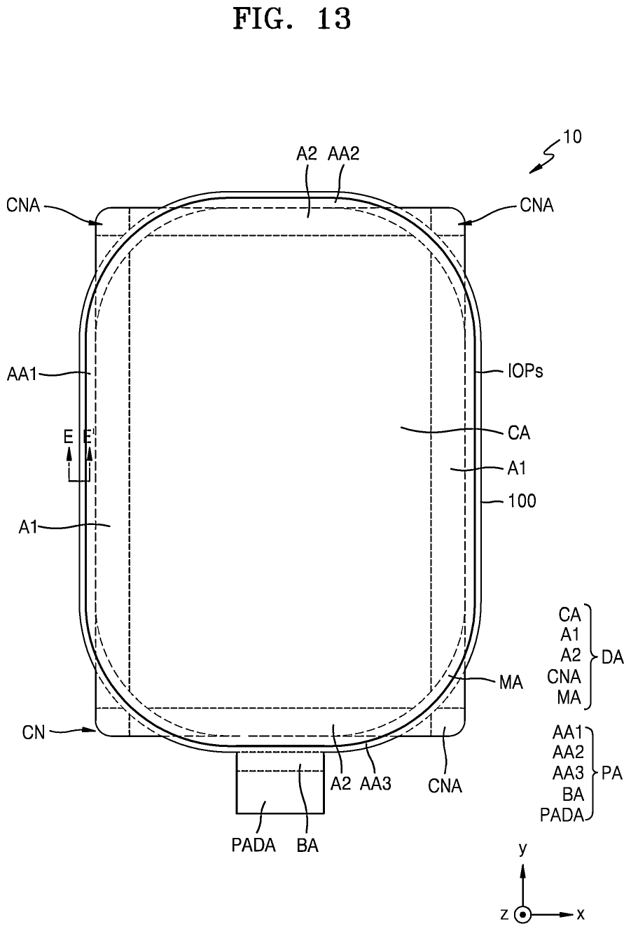

FIG. 13 is a plan view of the display panel 10 included in a display device, according to an embodiment.

Referring to FIG. 13, the display panel 10 may include the substrate 100. The substrate 100 may include the display area DA and the peripheral area PA adjacent to the display area DA.

The display area DA may include the center area CA, the first area A1, the second area A2, the corner area CNA, and the intermediate area MA. The center area CA may be a flat area. According to an embodiment, the display panel 10 may provide most of the image in the center area CA.

The peripheral area PA may include the first adjacent area AA1, the second adjacent area AA2, the third adjacent area AA3, the bending area BA, and the pad area PADA. Accordingly, the peripheral area PA may be a non-display area where an image is not displayed.

According to an embodiment, the second opening IOPs may surround the center area CA, the first area A1, and the second area A2 in a plan view. According to an embodiment, as shown in FIG. 13, the second opening IOPs may be arranged in the first adjacent area AA, the second adjacent area AA2, the third adjacent area AA3, and the intermediate area MA, and the second opening IOPs may have a closed-loop shape surrounding the center area CA, the first area A1, and the second area A2, in a plan view.

According to another embodiment, the second opening IOPs may be arranged in each of the first adjacent area AA1, the second adjacent area AA2, and the third adjacent area AA3, along the edge of the substrate 100.

The display panel 10 may further include the first opening IOP described with reference to FIGS. 6A to 8B, 10, and 11.

According to an embodiment, the second inorganic encapsulation layer 330 (see FIG. 6B) may not be patterned in the center area CA that is a flat area among the display area DA, but may be integrally formed to cover an entire surface of the center area CA. The inorganic patterns IP (see FIG. 6B) that are spaced apart from each other may be arranged in only some of the first area A1, the second area A2, the corner area CNA, and the intermediate area MA, which are areas where the stress is concentrated, among the display area DA. In other words, the second inorganic encapsulation layer 330 (see FIG. 6B) may be patterned only in some of the first area A1, the second area A2, the corner area CNA, and the intermediate area MA, to define the first opening IOP (see FIG. 6B).

According to another embodiment, the inorganic patterns IP (see FIG. 6B) may be arranged throughout the display area DA. In other words, the second inorganic encapsulation layer 330 (see FIG. 6B) may be patterned throughout the display area DA to define the first opening IOP (see FIG. 6B).

According to an embodiment, elongation of a display panel may be increased by including inorganic patterns that are spaced apart from each other. Accordingly, damage caused in case that stress is concentrated on a portion of the display panel may be prevented or reduced, and thus, a display device having enhanced reliability may be provided. The scope of the disclosure is not limited by such effects.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate including a display area and a peripheral area adjacent to the display area;
a plurality of light-emitting diodes arranged in the display area;
a first inorganic encapsulation layer disposed on the plurality of light-emitting diodes;
an organic encapsulation layer disposed on the first inorganic encapsulation layer;
a plurality of inorganic patterns disposed on the organic encapsulation layer and spaced apart from each other; and
a touch electrode disposed on the organic encapsulation layer and defining a plurality of electrode holes respectively overlapping the plurality of light-emitting diodes in a plan view.

2. The display device of claim 1, wherein
each of the plurality of inorganic patterns covers one of the plurality of light-emitting diodes in a plan view, and
the plurality of inorganic patterns are respectively arranged inside the plurality of electrode holes in a plan view.

3. The display device of claim 1, wherein
each of the plurality of inorganic patterns covers two or more of the plurality of light-emitting diodes in a plan view, and
each of the plurality of inorganic patterns overlaps two or more of the plurality of electrode holes in a plan view.

4. The display device of claim 1, wherein
a first opening is defined between the plurality of inorganic patterns, and
the first opening overlaps at least a portion of the touch electrode in a plan view.

5. The display device of claim 4, wherein
a portion of the touch electrode, which overlaps the first opening in a plan view, is in direct contact with the organic encapsulation layer, and
a remaining portion of the touch electrode is disposed on the plurality of inorganic patterns.

6. The display device of claim 4, wherein the plurality of inorganic patterns comprise a first inorganic layer and a second inorganic layer.

7. The display device of claim 4, further comprising:
a first inorganic layer disposed on the plurality of inorganic patterns and covering the first opening,
wherein the touch electrode is disposed on the first inorganic layer.

8. The display device of claim 4, further comprising:
an organic layer disposed on the plurality of inorganic patterns and filling the first opening,
wherein the touch electrode is disposed on the organic layer.

9. The display device of claim 1, wherein
each of the plurality of light-emitting diodes comprises a pixel electrode, an opposing electrode, and an emission layer arranged between the pixel electrode and the opposing electrode,
the display device further comprises:
a pixel-defining layer defining a plurality of pixel openings exposing center portions of pixel electrodes; and
a metal bank layer disposed on the pixel-defining layer, including a first sub-metal layer and a second sub-metal layer on the first sub-metal layer, and defining a plurality of openings overlapping the plurality of pixel openings in a plan view, and
the second sub-metal layer comprises tips protruding from a side surface of the first sub-metal layer to a center direction of each of the plurality of pixel openings.

10. The display device of claim 9, wherein the opposing electrode is in direct contact with the side surface of the first sub-metal layer.

11. The display device of claim 9, wherein the first inorganic encapsulation layer is in direct contact with a bottom surface of the tips and the side surface of the first sub-metal layer.

12. The display device of claim 9, wherein a width of each of the plurality of inorganic patterns is greater than a width of ones of the plurality of pixel openings overlapping the plurality of inorganic patterns in a plan view.

13. The display device of claim 1, further comprising:
a common voltage line arranged in the peripheral area; and
a second inorganic encapsulation layer disposed on the organic encapsulation layer and overlapping the common voltage line in a plan view,
wherein the second inorganic encapsulation layer defines a second opening extending in a direction parallel to an edge of the substrate.

14. The display device of claim 13, wherein the second opening overlaps the organic encapsulation layer in a plan view.

15. The display device of claim 13, wherein the second opening surrounds at least a portion of the display area in a plan view.

16. A display device comprising:
a substrate including a display area and a peripheral area adjacent to the display area;
a plurality of light-emitting diodes arranged in the display area;
a first inorganic encapsulation layer disposed on the plurality of light-emitting diodes and extending to the peripheral area;
an organic encapsulation layer disposed on the first inorganic encapsulation layer; and
a second inorganic encapsulation layer disposed on the organic encapsulation layer and defining a first opening in the peripheral area.

17. The display device of claim 16, wherein the first opening overlaps the organic encapsulation layer in a plan view.

18. The display device of claim 16, further comprising:
a common voltage line arranged in the peripheral area and surrounding at least a portion of the display area in a plan view;
an organic insulating layer arranged between the substrate and the plurality of light-emitting diodes, and overlapping a boundary of the common voltage line at one side by extending from the display area to the peripheral area in a plan view; and
a dam overlapping a boundary of the common voltage line at another side in a plan view.

19. The display device of claim 18, wherein the first opening is disposed closer to the display area than to an end of the organic insulating layer.

20. The display device of claim 16, wherein the peripheral area is bent with a curvature in a rear direction of the substrate.
